(19) United States
(12) Patent Application Publication
(10) Pub. No.: US 2008/0160449 A1
(43) Pub. Date: Jul. 3, 2008

(54) Photoresist polymer having nano-smoothness and etching resistance, and resist composition

(75) Inventors: Yoshiyasu Kubo, Tokyo (JP); Yukihiro Kaneko, Tokyo (JP); Kaoru Suzuki, Tokyo (JP); Minoru Tamura, Tokyo (JP); Mineko Horibe, Tokyo (JP); Akinori Uno, Tokyo (JP); Hiroo Kinoshita, Hyogo (JP); Takeo Watanabe, Hyogo (JP)

Correspondence Address: HOFFMANN & BARON, LLP, 6900 JERICHO TURNPIKE, SYOSSET, NY, 11791, US

(73) Assignees: Lion Corporation, Tokyo (JP); Hyogo Prefecture, Hyogo (JP)

(21) Appl. No.: 12/069,979

(22) Filed: Feb. 12, 2008

Related U.S. Application Data
(63) Continuation of application No. PCT/JP2006/308634, filed on Apr. 25, 2006.

(30) Foreign Application Priority Data
Aug. 12, 2005 (JP) 2005-234801

(51) Int. Cl. G03F 7/004

(52) U.S. Cl. 430/286.1

(57) ABSTRACT

The present invention provides a hyperbranched polymer that is capable of being used as a polymer material for nanofabrication including lithography, has enhanced dry etching resistance, sensitivity and surface smoothness, has a core shell structure and has an acid degradable repeating unit of tert-butyl vinylbenzoate ester in a shell portion, and a resist composition containing the hyperbranched polymer.

### CROSS-REFERENCE TO RELATED APPLICATIONS

The present application is a continuation of PCT Application No. PCT/JP2006/308634, filed Apr. 25, 2006, which claims priority to Japanese Patent Application No. 2005-234801, filed Aug. 12, 2005, the contents of which are incorporated herein by reference.

### BACKGROUND OF THE INVENTION

1. Field of the Invention

The present invention relates to a resist composition including a hyperbranched polymer suitable as a macromolecular material for nanofabrication, particularly extreme ultraviolet (EUV) lithography focusing on photolithography as a base polymer of a resist material, and being capable of forming a fine pattern for producing VLSI.

2. Description of the Related Art

In recent years, in photolithography considered to be promising as microfabrication technology, miniaturization of design tools has been advanced by shortening the wavelength of a light source, realizing highly integrated VLSI. EUV lithography is considered to be promising in design tools for 45 nm or less.

In resist compositions, a base polymer having a transparent chemical structure for each light source has been developed. For example, the resist composition including novolak type polyphenol as a basic skeleton (see Japanese Patent Application Laid-Open Publication No. 2004-231858) for KrF excimer laser light (wavelength: 248 nm), the resist composition including poly(meth)acrylate ester (see Japanese Patent Application Laid-Open Publication No. 2004-359929) for ArF excimer laser light (wavelength: 193 nm), or the resist composition including a polymer introducing fluorine atoms (perfluoro structure) (see Japanese Patent Application Laid-Open Publication No. 2005-91428) for F2 excimer laser light (wavelength: 157 nm) have been proposed, and these polymers have a linear structure as the basic structure.

However, when these linear polymers are applied to the formation of hyperfine patterns for 45 nm or finer, asperity of a pattern wall detected by line edge roughness as an indicator has become problematic.

In non-patent literature (Franco Cerrina, Vac. Sci. Tech. B., 19, 2890 (2001)), it is pointed out that to form ultrafine patterns on conventional resists using mainly polymethyl methacrylate (PMMA) and polyhydroxystyrene (PHS) by exposing electron beams or extreme ultraviolet (EUV) ray, it becomes a problem to control the surface smoothness at a nano level.

According to Toru Yamaguti, Jpn. J. Appl. Phys., 38, 7114 (1999), the asperity of the pattern side wall is generated due to association of the polymers that compose the resist, and many reports are provided regarding technology to inhibit a molecular association of the polymer. For example, in the literature, as a procedure to enhance the surface smoothness of an electron beam positive resist, it has been reported that the introduction of a crosslinking structure into the linear polymer is effective.

Also, as an example of branched polymers that enhance the line edge roughness compared with the linear molecules, an electron beam resist including branched polyester composed of a phenol derivative having carboxyl group has been reported by Alexander R. Trimble, Proceedings of SPIE, 3999, 1198 (2000), but adhesiveness to the substrate is poor.

In Japanese Patent Application Laid-Open Publication No. 2000-347412 and Japanese Patent Application Laid-Open Publication No. 2001-324813, a resist composition including a polymer obtained by branching, binding and linking a straight phenol derivative backbone by chloromethylstyrene has been proposed, but an exposure sensitivity is several tens mJ/cm², which does not satisfy high sensitivity requirements for the miniaturization of the design tools.

Further, in Japanese Patent Application Laid-Open Publication No. 2005-53996 and Japanese Patent Application Laid-Open Publication No. 2005-70742 a resist composition including a star type branched polymer obtained by binding multiple polymer chains to a lower alkyl molecule has been proposed. However, the exposure sensitivity is several tens mJ/cm², which is low. In addition, since a (meth)acrylate ester monomer is contained in a polymerization unit, dry etching resistance is low. Thus, this resist composition is difficult to apply to a 32 nm process in which a resist coating film is thinned along with shortening the wavelength of the light source.

In Japanese Patent Application Laid-Open Publication No. 2000-500516, Japanese Patent Application Laid-Open Publication No. 2000-514479, and literature (Krzysztof Matyjaszewski, Macromolecules, 29, 1079 (1996); Jean M. Frecht, J. Poly. Sci., 36, 955 (1998)), it has been reported that to highly branch a styrene derivative that is a macromolecule that becomes a main body of the lithography, it is possible to control the branching degree and a weight average molecular weight of chloromethylstyrene by living radical polymerization. However, no molecular design to impart workability by the exposure and required for the resist has been made. In International Publication No. 2005/061566 Pamphlet, as a procedure to solve the shortages, a hyperbranched polymer having a core shell structure has been proposed. The present invention takes advantage of characteristics of the hyperbranched polymer that is excellent in exposure sensitivity and line edge roughness as well as enhances an etching resistance by employing a particular repeating unit that is not described in International Publication No. 2005/061566 Pamphlet as the repeating unit that composes a shell portion.

### SUMMARY OF THE INVENTION

The present invention has been made in the light of the circumstance, and aims at providing a hyperbranched polymer capable of being utilized as a polymer material for nanofabrication focusing on photolithography and having enhanced dry etching resistance, sensitivity, surface smoothness and line edge toughness, and a resist composition including the hyperbranched polymer.

As a result of extensive study to solve the problems, the present inventors have obtained the following findings. That is, it has been found that an exposed portion of a hyperbranched polymer obtained by employing a particular repeating unit at a polymer end is efficiently dissolved in an alkaline solution and removed with the alkaline solution, and thus, a fine pattern can be formed and a high sensitivity can be obtained. Furthermore, it has been found to have an excellent dry etching resistance. It has been also found to be capable of being utilized suitably as a base resin of a resist material.

The present invention has been made based on the findings of the present inventors. That is, the present invention provides a hyperbranched polymer having a core

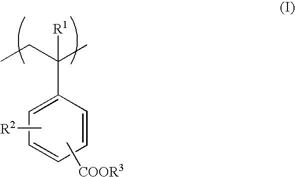

shell structure containing a repeating unit represented by the following formula (I) in a shell portion.

### (Chemical 1)

Where, R¹ represents a hydrogen atom or an alkyl group having 1 to 3 carbon atoms; R² represents a hydrogen atom, a straight, branched or cyclic alkyl group having 1 to 30 carbon atoms or an aryl group having 6 to 30 carbon atoms; R³ represents a hydrogen atom, a straight, branched or cyclic alkyl group having 1 to 40 carbon atoms, a trialkylsilyl group (here alkyl groups have each independently 1 to 6 carbon atoms), an oxoalkyl group (here the alkyl group has 4 to 20 carbon atoms), or a group represented by a following formula (I):

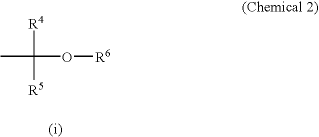

Where, R⁴ represents a straight, branched or cyclic alkyl group having 1 to 10 carbon atoms, and R⁵ and R⁶ each independently represent a straight, branched or cyclic alkyl group having 1 to 10 carbon atoms or R⁵ and R⁶ may be taken together to form a ring.

The present invention also provides a resist composition containing the hyperbranched polymer.

The other objects, features, and advantages of the present invention are specifically set forth in or will become apparent from the following detailed description of the invention.

### DETAILED DESCRIPTION OF THE PREFERRED EMBODIMENTS

The hyperbranched polymer according to the present invention is composed of a core portion and a shell portion present around it.

### (Shell Portion)

The shell portion of the hyperbranched polymer according to the present invention composes an end of the polymer and has at least a repeating unit represented by the formula (I). The repeating unit includes an acid degradable group that degrades by an action of an organic acid such as acetic acid, maleic acid or benzoic acid, or an inorganic acid such as hydrochloric acid, sulfuric acid or nitric acid, preferably by an action of a photo acid generator that generates the acid by light energy. It is preferable that the acid degradable group degrades to become a hydrophilic group.

R¹ in the formula (I) represents a hydrogen atom or an alkyl group having 1 to 3 carbon atoms. Among them, the hydrogen atom and methyl group are preferable.

R² represents a hydrogen atom; a straight, branched or cyclic alkyl group having 1 to 30 carbon atoms, preferably 1 to 20 carbon atoms, more preferably 1 to 10 carbon atoms; or an aryl group having 6 to 30 carbon atoms, preferably 6 to 20 carbon atoms and more preferably 6 to 10 carbon atoms. The straight, branched or cyclic alkyl group includes methyl, ethyl, propyl, isopropyl, butyl, isobutyl, t-butyl and cyclohexyl groups. The aryl group includes phenyl, 4-methylphenyl and naphthyl groups. Among them, the hydrogen atom, methyl, ethyl and phenyl groups are preferable. The hydrogen atom is the most preferable.

R³ represents a hydrogen atom; a straight, branched or cyclic alkyl group having 1 to 40 carbon atoms, preferably 1 to 30 carbon atoms, more preferably 1 to 20 carbon atoms; a trialkylsilyl group (here, each alkyl group has 1 to 6 carbon atoms and preferably 1 to 4 carbon atoms); an oxoalkyl group (here, each alkyl group has 4 to 20 carbon atoms and preferably 4 to 10 carbon atoms); or the group represented by the formula (I) (R⁴ represents a hydrogen atom or a straight, branched or cyclic alkyl group having 1 to 10 carbon atoms, preferably 1 to 8 carbon atoms, more preferably 1 to 6 carbon atoms, and R⁵ and R⁶ each independently represent hydrogen atoms or straight, branched or cyclic alkyl groups having 1 to 10 carbon atoms, preferably 1 to 8 carbon atoms, more preferably 1 to 6 carbon atoms, or alternatively they may form a ring together). Among them, the straight, branched or cyclic alkyl group has 1 to 40 carbon atoms, preferably 1 to 30 carbon atoms, more preferably 1 to 20 carbon atoms. The branched alkyl group having 1 to 20 carbon atoms is more preferable.

In the R³, the straight, branched or cyclic alkyl group includes ethyl, propyl, isopropyl, butyl, isobutyl, t-butyl, cyclopentyl, cyclohexyl, cycloheptyl, triethylcarbyl, 1-ethylnorbornyl, 1-methylcyclohexyl, adamantyl, 2-(2-methyl)adamantyl, and tert-amyl groups. Among them, t-butyl group is particularly preferable.

In the R³, a trialkylsilyl group includes trimethylsilyl, triethylsilyl and dimethyl-tert-butylsilyl groups, each alkyl group having 1 to 6 carbon atoms. An Oxoalkyl group includes a 3-oxocyclohexyl group.

The group represented by the formula (I) includes straight or branched acetal groups such as 1-methoxyethyl, 1-ethoxyethyl, 1-n-propoxyethyl, 1-isopropoxyethyl, 1-n-butoxyethyl, 1-isobutoxyethyl, 1-sec-butoxyethyl, 1-tert-butoxyethyl, 1-tert-amyloxyethyl, 1-ethoxy-n-propyl, 1-cyclohexylethyl, methoxypropyl, ethoxypropyl, 1-methoxy-1-methyl-ethyl and 1-ethoxy-1-methyl-ethyl groups; and cyclic acetal groups such as tetrahydrofuranyl and tetrahydropyranyl. Among them, ethoxyethyl, butoxyethyl, ethoxypropyl and tetrahydropyranyl groups are particularly suitable.

A monomer that gives the repeating unit represented by the formula (I) includes vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1-n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butylolactone, β-(4-vinylbenzoyl)oxy-γ-butylolactone, γ-(4-vinylbenzoyl)oxy-γ-butylolactone, α-methyl-α-(4-vinylbenzoyl)oxy-γ-butylolactone, β-methyl-β-(4-vinylbenzoyl)oxy-γ-butylolactone, γ-methyl-γ-(4-vinylbenzoyl)oxy-γ-butylolactone, α-ethyl-α-(4-vinylbenzoyl)oxy-γ-butylolactone, β-ethyl-β-(4-vinylbenzoyl)oxy-γ-butylolactone, γ-ethyl-γ-(4-vinylbenzoyl)oxy-γ-butylolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxypentyl vinylbenzoate, trimethylolpropane vinylbenzoate, glycidyl vinylbenzoate, benzyl vinylbenzoate, phenyl vinylbenzoate and naphthyl vinylbenzoate. Among them, tert-butyl vinylbenzoate is preferable. Particularly tert-butyl 4-vinylbenzoate is preferable.

Monomers other than the monomers that give the repeating unit represented by the formula (I) can also be used as the monomer that forms the shell portion provided they have a structure that has a radical polymerizable unsaturated bond.

Copolymerization monomers that can be used include compounds having a radical polymerizable unsaturated bond, selected from styrenes other than the above, and acrylate esters, methacrylate esters, and allyl compounds, vinyl ethers, vinyl esters, crotonate esters and the like.

Specific examples of styrenes include tert-butoxystyrene, α-methyl-tert-butoxystyrene, 4-(1-methoxyethoxy)styrene, 4-(1-ethoxyethoxy)styrene, tetrahydropyranyloxystyrene, adamantyloxystyrene, 4-(2-methyl-2-adamantyloxy)styrene, 4-(1-methylcyclohexyloxy)styrene, trimethylsilyloxystyrene, dimethyl-tert-butylsilyloxystyrene, tetrahydropyranyloxystyrene, benzylstyrene, trifluoromethystyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene and vinyl naphthalene.

Specific examples of acrylate esters include tert-butyl acrylate, 1-methylcyclohexyl acrylate, adamantyl acrylate, 2-(2-methyl)adamantyl acrylate, triethylcarbyl acrylate, 1-ethylnorbornyl acrylate, 1-methylcyclohexyl acrylate, tetrahydropyranyl acrylate, trimethylsilyl acrylate and dimethyl-tert-butylsilyl acrylate. Among them, tert-butyl acrylate, 2-(2-methyl)adamantyl acrylate, tetrahydropyranyl acrylate, chloroethyl acrylate, 2-hydroxyethyl acrylate, 2,2-dimethylhydroxypropyl acrylate, 5-hydroxypentyl acrylate, trimethylolpropane acrylate, glycidyl acrylate, benzyl acrylate, phenyl acrylate, and naphthyl acrylate are included.

Specific examples of methacrylate esters include tert-butyl methacrylate, benzyl methacrylate, chlorobenzyl methacrylate, 2-hydroxyethyl methacrylate, 4-hydroxybutyl methacrylate, 5-hydroxypentyl methacrylate, 2,2-dimethyl-3-hydroxypropyl methacrylate, glycidyl methacrylate, phenyl methacrylate, naphthyl methacrylate, adamantyl methacrylate, 2-(2-methyl)adamantyl methacrylate, tetrahydropyranyl methacrylate and 1-methylcyclohexyl methacrylate.

Specific examples of allyl esters include allyl acetate, allyl caproate, allyl caprylate, allyl laurate, allyl palmitate, allyl stearate, allyl benzoate, allyl acetoacetate, allyl lactate and allyloxy ethanol.

Specific examples of vinyl ethers include hexylvinyl ether, octylvinyl ether, decylvinyl ether, ethylhexylvinyl ether, methoxyethylvinyl ether, ethoxyethylvinyl ether, chloroethylvinyl ether, 1-methyl-2,2-dimethylpropylvinyl ether, 2-ethylbutylvinyl ether, hydroxyethylvinyl ether, diethylene glycol vinyl ether, dimethylaminoethylvinyl ether, diethylaminoethylvinyl ether, butylaminoethylvinyl ether, benzylvinyl ether, tetrahydrofurfurylvinyl ether, vinylphenyl ether, vinyltolyl ether, vinylchlorophenyl ether, vinyl-2,4-dichlorophenyl ether, vinylnaphthyl ether and vinylanthranil ether.

Specific examples of vinyl esters include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate and vinyl cyclohexylcarboxylate.

Specific examples of crotonate esters include butyl crotonate, hexyl crotonate, glycerine monocrotonate, dimethyl itaconate, diethyl itaconate, dibutyl itaconate, dimethyl fumarate, dibutyl fumarate, maleic acid anhydrate, maleimide, acrylonitrile, methacrylonitrile and maleilonitrile.

The following formulae are also included.

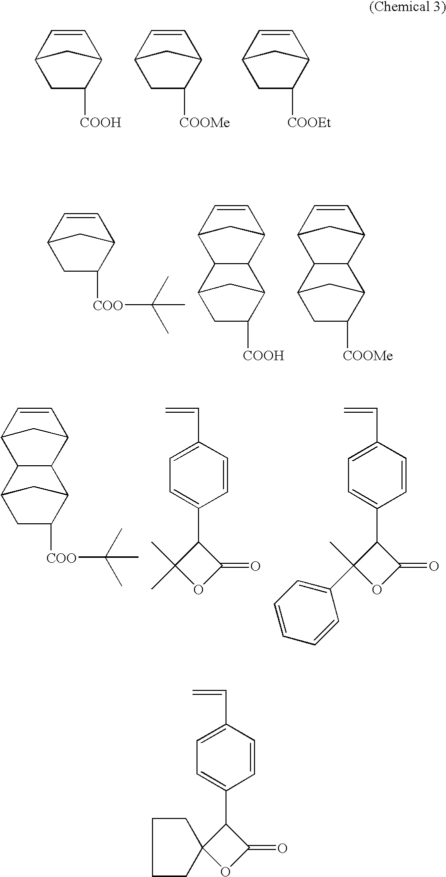

Among them, styrenes, acrylate esters, methacrylate esters and crotonate esters are preferable, and among others, benzylstyrene, chlorostyrene, vinylnaphthalene, tert-butyl acrylate, benzyl acrylate, phenyl acrylate, naphthyl acrylate, tert-butyl methacrylate, benzyl methacrylate, phenyl methacrylate, naphthyl methacrylate, butyl crotonate, hexyl crotonate and maleic acid anhydrate are preferable.

### (Core Portion)

The monomer that forms the core portion of the hyperbranched polymer of the present invention is not particularly limited as long as living radical polymerization is possible, and can be appropriately selected depending on the purpose. For example, the monomers represented by the following formula (II) and the other monomers having the radical polymerizable unsaturated bond can be included. The monomers that give the repeating unit represented by the formula (I) can also be used. Among them, the compound obtained by homopolymerizing the monomer represented by the following formula (II), the compound obtained by copolymerizing the monomer represented by the following formula (II) and the monomer that gives the repeating unit represented by the formula (I), and the compound obtained by copolymerizing the monomer represented by the following formula (II) and the other monomer having the radical polymerizable unsaturated bond are preferable.

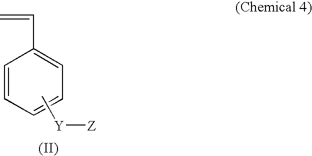

In the formula (II), Y represents a straight, branched or cyclic alkylene group having 1 to 10 carbon atoms, preferably 1 to 8 carbon atoms and more preferably 1 to 6 carbon atoms, which may include hydroxyl or carboxyl group, and for example, methylene, ethylene, propylene, isopropylene, butylene, isobutylene, amylene, hexylene and cyclohexylene groups, and groups to which these are bound, or groups where —O—, —CO— or —COO— is present in these groups are included. Among them, the alkylene group having 1 to 8 carbon atoms is preferable, the straight alkylene group having 1 to 8 carbon atoms is more preferable, and methylene, ethylene, —OCH₂— and —OCH₂CH₂— groups are still more preferable.

Z represents a halogen atom such as a fluorine, chlorine, bromine or iodine, and among them, the chlorine atom or the bromine atom is preferable.

The monomer represented by the formula (II), which can be used in the present invention includes, for example, chloromethylstyrene, bromomethylstyrene, p-(1-chloroethyl)styrene, bromo(4-vinylphenyl)phenylmethane, 1-bromo-1-(4-vinylphenyl)propane-2-one and 3-bromo-3-(4-vinylphenyl)propanol. Among them, chloromethylstyrene, bromomethylstyrene and p-(1-chloroethyl)styrene are preferable.

In the hyperbranched polymer of the present invention, a lower limit of the monomer that gives the repeating unit represented by the formula (I) is preferably 10 mol % or more, preferably 20 mol % or still more preferably 30 mol % or more, and an upper limit thereof is preferably 90 mol % or less and more preferably 80 mol % or less. It is suitable that the monomer is contained at the range of 10 to 90 mol %, preferably 20 to 80 mol % and more preferably 30 to 80 mol % in the polymer. In particular, it is suitable that the repeating unit represented by the formula (I) is contained at the range of 50 to 100 mol %, preferably 80 to 100 mol % in the shell portion. Such a range is preferable because the exposed portion is efficiently dissolved in the alkaline solution and removed in a development step.

Furthermore, such a range is preferable because functions such as dry etching resistance, wettability and elevation of a glass transition temperature are imparted without inhibiting an efficient solubility of the exposed portion in the alkaline solution. The amount of the repeating unit represented by the formula (I) and the amount of the repeating unit other than it in the shell portion can be controlled by a feeding amount ratio at molar ratio upon introduction of the shell portion depending on the purpose.

It is suitable that the monomer represented by the formula (II) is contained in an amount of 5 to 100 mol %, preferably 20 to 100 mol %, and more preferably 50 to 100 mol % relative to the total monomers that form the core portion in the hyperbranched polymer of the present invention. Such a range is preferable because the core portion takes a spherical form that is advantageous for inhibiting an entanglement among the molecules.

In the hyperbranched polymer of the present invention, the lower limit of the monomer that forms the core portion is preferably 10 mol % or more, preferably 20 mol % or more, and the upper limit thereof is preferably 90 mol % or less, more preferably 80 mol % or less and still more preferably 60 mol % or less relative to the total monomers. It is suitable that the monomer is contained in the amount of 10 to 90 mol %, preferably 20 to 80 mol % and more preferably 20 to 60 mol %. It is preferable that the amount of the monomer that composes the core portion is within such a range because the dissolution of an unexposed portion is inhibited due to having an appropriate hydrophobicity for a developer.

When the core portion in the hyperbranched polymer of the present invention is obtained by copolymerizing the monomer represented by the formula (II) and the monomer that gives the repeating unit represented by the formula (I), the amount of the monomer represented by the formula (II) in the total monomers is preferably 10 to 99 mol %, more preferably 20 to 99 mol % and suitably 30 to 99 mol %. It is preferable that the monomer represented by the formula (II) is contained in such an amount because the core portion takes a spherical form that is advantageous for inhibiting the entanglement among the molecules.

When a monomer other than those represented by the formulae (II) and (I) is used as the monomer that composes the core portion, the percentage of the monomers represented by the formulae (II) and (I) in the total monomers that compose the core portion is preferably 40 to 90 mol % and more preferably 50 to 80 mol %. It is preferable that the monomers represented by the formulae (II) and (I) are used in such an amount because the functions such as adhesiveness to the substrate and elevation of the glass transition temperature are imparted. The amounts of the monomers represented by the formulae (II) and (I) and the amount of the monomer other than them in the core portion can be controlled by the feeding amount ratio upon polymerization depending on the purpose.

The other monomers having the radical polymerizable unsaturated bond are compounds having the radical polymerizable unsaturated bond selected from styrenes and acrylate esters, methacrylate esters, and allyl compounds, vinyl ethers, and vinyl esters.

Specific examples of styrenes include styrene, α-styrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene and vinylnaphthalene.

Specific examples of acrylate esters include chloroethyl acrylate, 2-hydroxyethyl acrylate, 2,2-dimethylhydroxypropyl acrylate, 5-hydroxypentyl acrylate, trimethylolpropane acrylate, glycidyl acrylate, benzyl acrylate, phenyl acrylate and naphthyl acrylate.

Specific examples of methacrylate esters include benzyl methacrylate, chlorobenzyl methacrylate, 2-hydroxyethyl methacrylate, 4-hydroxybutyl methacrylate, 5-hydroxypentyl methacrylate, 2,2-dimethylhydroxypropyl methacrylate, glycidyl methacrylate, phenyl methacrylate and naphthyl methacrylate.

Specific examples of allyl esters include allyl acetate, allyl caproate, allyl caprylate, allyl laurate, allyl palmitate, allyl stearate, allyl benzoate, allyl acetoacetate, allyl lactate and allyloxy ethanol.

Specific examples of vinyl ethers include hexylvinyl ether, octylvinyl ether, decylvinyl ether, ethylhexylvinyl ether, methoxyethylvinyl ether, ethoxyethylvinyl ether, chloroethylvinyl ether, 1-methyl-2,2-dimethylpropylvinyl ether, 2-ethylbutylvinyl ether, hydroxyethylvinyl ether, diethylene glycol vinyl ether, dimethylaminoethylvinyl ether, diethylaminoethylvinyl ether, butylaminoethylvinyl ether, benzylvinyl ether, tetrahydrofurfurylvinyl ether, vinylphenyl ether, vinyltolyl ether, vinylchlorophenyl ether, vinyl-2,4-dichlorophenyl ether, vinylnaphthyl ether and vinylanthranil ether.

Specific examples of vinyl esters include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate and vinyl cyclohexylcarboxylate.

Among them, styrenes are preferable, and among others, benzylstyrene, chlorostyrene and vinylnaphthalene are preferable.

The hyperbranched polymer of the present invention can be produced by a core portion synthesizing step of synthesizing the hyperbranched polymer from the living radical polymerizable monomer and by reacting the synthesized hyperbranched polymer with at least the monomer that gives the repeating unit represented by the formula (I) to form the shell portion having the acid degradable group around the core portion.

### (Step of Synthesizing Core Portion)

Taking the case in which the monomer represented by the formula (II) is used as the monomer that composes the core portion for instance, the step will be described. The core portion of the hyperbranched polymer of the present invention can be produced by performing the living radical polymerization of the raw material monomer in a solvent such as chlorobenzene typically at 0 to 200° C. for 0.1 to 30 hours.

Y-Z bond in the formula (II) is radically dissociated reversibly by a transition metal complex to inhibit the termination reaction between two molecules, whereby the living radical polymerization reaction progresses.

For example, when chloromethylstyrene is used as the monomer represented by the formula (II) and a copper (monovalent) bipyridyl complex is used as a catalyst, a chlorine atom in chloromethylstyrene forms an adduct as an intermediate in a state where monovalent copper is oxidized to bivalent copper, and methylene radical is generated at the side where the chlorine atom has been removed (see Krzysztof Matyjaszewski, Macromolecules, 29, 1079 (1996) and Jean M. J. Frecht, J. Poly. Sci., 36, 955 (1998)).

This radical intermediate is reacted with an ethylenic double bond of other chloromethylstyrene to form a dimer represented by the following formula (V). At that time, a primary carbon (a) and a secondary carbon (b) generated in the molecule have a chlorine group as a substituent. Thus, each is further reacted with the ethylenic double bond of other chloromethylstyrene. Hereinafter, the same applies to sequentially cause the polymerization with chloromethylstyrene.

Also in a tetramer represented by the following formula (VI), the primary carbons (C) and (d) and the secondary carbons (e) and (f) have the chlorine group as the substituent. Thus, each is further reacted with the ethylenic double bond of other chloromethylstyrene. Hereinafter, the same applies to repeat the reaction, thereby generating a highly branched macromolecule.

When the amount of the copper complex that is the catalyst is increased at that time, a branching degree is increased. The amount of the catalyst to be used is preferably 0.1 to 60 mol %, more preferably 1 to 60 mol % and still more preferably 1 to 40 mol % relative to the total amount of the monomer represented by the formula (II). When the catalyst is used in such an amount, it is possible to yield the hyperbranched polymer core portion having the suitable branching degree described later.

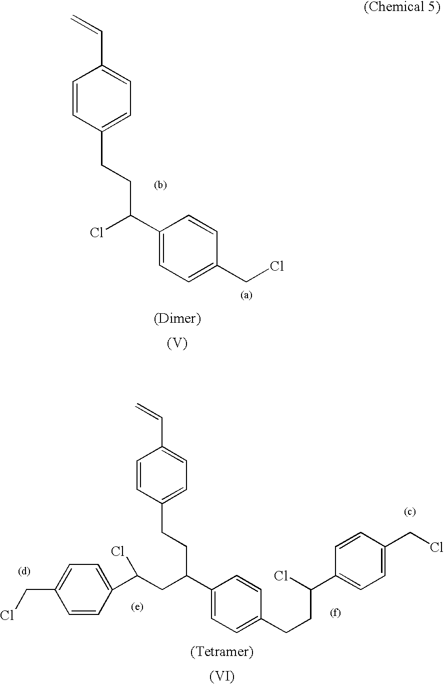

When the core portion is obtained by copolymerizing the monomer represented by the formula (II) and the monomer that gives the repeating unit represented by the formula (I), the core portion can be produced by performing the living radical polymerization using the transition metal complex by the same technique as in the case of homopolymerizing the monomer represented by the formula (II).

### (Step of Introducing Shell Portion)

In the hyperbranched polymer of the present invention, the shell portion can be introduced at polymer ends by reacting the core portion synthesized as the above of the hyperbranched polymer with the compound containing the acid degradable group.

### (First Method)

After isolating the core portion obtained in the step of synthesizing the core portion of the hyperbranched polymer, for example, using the monomer that gives the repeating unit represented by the formula (I) as the monomer having the acid degradable group, it is possible to introduce the acid degradable group represented by the formula (I).

As the catalyst, using the same transition metal complex as the catalyst used for the synthesis of the core portion of the hyperbranched polymer, for example, using the monovalent copper bipyridyl complex, utilizing halogenated carbon atoms abundantly present at the ends of the core portion as an initiation point, a straight addition polymerization is performed by the living radical polymerization with the double bonds of at least one compound including the monomer that gives the repeating unit represented by the formula (I). Specifically, it is possible to introduce the acid degradable group represented by the formula (I) to produce the hyperbranched polymer of the present invention by reacting the core portion with at least one compound including the monomer that gives the repeating unit represented by the formula (I) in the solvent such as chlorobenzene typically at 0 to 200° C. for 0.1 to 30 hours.

As one example, a reaction formula to introduce the acid degradable group into the core portion of the hyperbranched polymer formed from chloromethylstyrene is shown in the reaction formula 1.

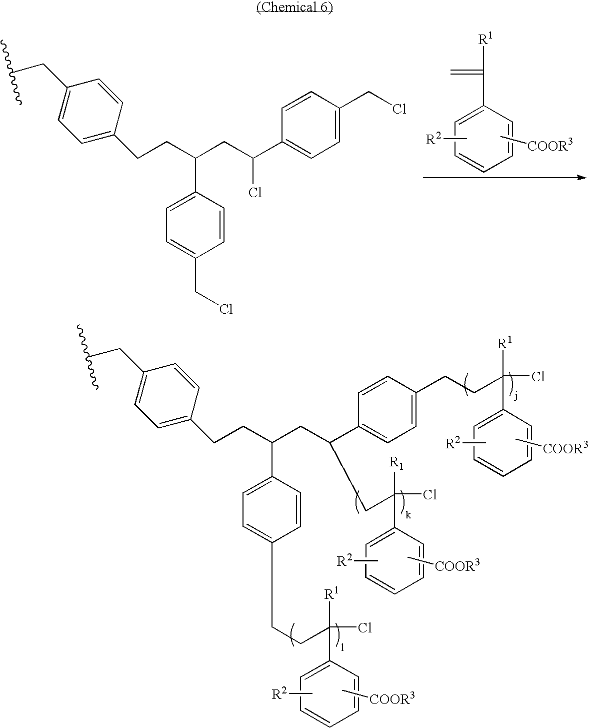

Each y, j, k or l is a numeral of 1 or more, and y≧j≧0, y≧k≧0, y≧l≧0, but y≧j+k+l≧0

Reaction Equation 1

### (Second Method)

Using the step of synthesizing the core portion of the hyperbranched polymer, the acid degradable group can be introduced without isolating the core portion after polymerizing the core portion by using the monomer that gives the repeating unit represented by the formula (I) as the compound containing the acid degradable group.

A ratio of the acid degradable group introduced in the hyperbranched polymer of the present invention is preferably 0.05 to 20, more preferably 0.1 to 20, more preferably 0.3 to 20, still more preferably 0.3 to 15, still more preferably 0.5 to 10 and most preferably 0.6 to 8 relative to the number of the monomer represented by the formula (II) that composes the core portion of the hyperbranched polymer. It is preferable to be within such a range because the exposed portion is efficiently dissolved in and removed with the alkali solution and the dissolution of the unexposed portion is inhibited in the development step, which are advantageous for forming the fine pattern.

In the hyperbranched polymer of the present invention, the acid degradable group that composes the hyperbranched polymer may be converted into an acidic group such as carboxyl group or a phenolic hydroxy group after being introduced into the core portion by a partial degradation reaction using the catalyst, e.g., a de-esterification reaction. In this case, the degradation reaction can be performed up to about 80% of the total acid degradable group.

Specific examples of the catalyst include acid catalysts such as hydrochloric acid, sulfuric acid, phosphoric acid, hydrobromic acid, para-toluenesulfonic acid, acetic acid, trifluoroacetic acid, trifluoromethanesulfonic acid, and formic acid, or alkaline catalysts such as sodium hydroxide and potassium hydroxide. Preferably the acid catalysts, more preferably hydrochloric acid, para-toluenesulfonic acid, acetic acid, trifluoroacetic acid and formic acid are suitable.

A constitution mol percent of the repeating unit where R3 is the hydrogen atom in the formula (I) is 0 to 80%, preferably 0 to 70% and more preferably 0 to 60% relative to the hyperbranched polymer of the present invention. It is preferable to be within such a range because the sensitivity of the resist becomes high in the exposure step, which is advantageous.

Here, the ratio of the acid degradable group introduced can be obtained as a molar ratio by measuring ¹H-NMR of the product and calculating based on an integral value of a peak characteristic for the acid degradable group and an integral value of a peak of other components.

The branching degree (Br) of the core portion in the hyperbranched polymer is preferably 0.1 to 0.9, more preferably 0.3 to 0.7, still more preferably 0.4 to 0.5, and most preferably 0.5. It is preferable that the branching degree of the core portion is within such a range because the entanglement among polymer molecules is reduced and a surface roughness in the pattern side wall is inhibited.

Here, the branching degree can be obtained by measuring ¹H-NMR of the product and calculating as follows. That is, the branching degree can be calculated by the following equation 1 using the integral ratio H1° of proton at —CH2Cl position that appears at 4.6 ppm and the integral ratio H2° of proton at —CHCl position that appears at 4.8 ppm. When the polymerization progresses at both —CH2Cl position and —CHCl position and the branch is increased, the Br value comes close to 0.5.

$$Br = \frac{\frac{1}{2} H 1 °}{\frac{1}{2} H 1 ° + H 2 °} \qquad ( 1 )$$

A weight average molecular weight of the core portion in the hyperbranched polymer of the present invention is preferably 300 to 100,000, also preferably 500 to 80,000, more preferably 1,000 to 60,000, still more preferably 1,000 to 50,000 and most preferably 1,000 to 30,000. It is preferable that the molecular weight of the core portion is within such a range because the core portion takes the spherical form and the solubility in the reaction solvent can be endured in the introduction reaction of the acid degradable group. Furthermore, it is preferable because it is advantageous for inhibiting the dissolution of the unexposed portion in the hyperbranched polymer that is excellent in film-forming property and introduces the acid degradable group into the core portion in the molecular weight range.

The weight average molecular weight (M) of the hyperbranched polymer of the present invention is preferably 500 to 150,000, more preferably 2,000 to 150,000, still more preferably 1,000 to 100,000, still more preferably 2,000 to 60,000 and most preferably 3,000 to 60,000. When the weight average molecular weight (M) of the hyperbranched polymer is within such a range, the resist containing the hyperbranched polymer is good in film forming property, and can hold its shape because the strength of the processed pattern formed in a lithography step is sufficient. The resist is also excellent in dry etching resistance and good in surface roughness.

Here, the weight average molecular weight (Mw) of the core portion can be obtained by preparing 0.05% by weight tetrahydrofuran solution and performing GPC measurement at a temperature of 40° C. Tetrahydrofuran can be used as a mobile solvent and styrene can be used as a standard substance. The weight average molecular weigh (M) of the hyperbranched polymer of the present invention can be obtained by obtaining the introduction ratio (constituent ratio) of each repeating unit of the polymer to which the acid degradable group has been introduced by ¹H-NMR and calculating based on the weight average molecular weight (Mw) of the core portion of the hyperbranched polymer using the introduction ratio of each constituent unit and the molecular weight of each constituent unit.

When the hyperbranched polymer of the present invention is synthesized using the transition metal complex as the catalyst, the resulting hyperbranched polymer contains the transition metal in some cases. Its amount depends on the type and the amount of the catalyst used, and typically the transition metal in an amount of 7 to 5 ppm can be contained in the hyperbranched polymer. At that time, it is preferable that the metal derived from the catalyst contained in the hyperbranched polymer is removed so that its amount is less than 100 ppb, preferably less than 80 ppb and more preferably less than 60 ppb. When the amount of the metal derived from the catalyst is 100 ppb or more, the irradiated light is sometimes absorbed by the contaminated metal element to reduce the resist sensitivity and disturb throughput in the exposure step. Furthermore, in the step of removing the dry etching-treated resist by dry ashing with O₂ plasma, the contaminated metal element is sometimes adhered or diffused onto the substrate to bring various disturbances in post-steps. The amount of the metal element can be measured using ICPMAS (e.g., P-6000 type MIP-MS supplied from Hitachi, Ltd.). To remove it, the polymer or the solution of the polymer in the organic solvent is washed with ultra pure water. An ion exchange membrane (e.g., Protego supplied from Nihon Mykrolis K.K.) is used. A membrane film (e.g., Millipore filter supplied from Millipore) is used. Pressure may be added upon filtration. It is preferable to run the polymer solution at a flow rate of 0.5 to 10 mL/minute because this is advantageous for removing the metal element. It is preferable that the procedures are used alone or in combination.

The sensitivity can be obtained by using the ultraviolet light or the extreme ultraviolet light (EUV), irradiating the light at energy of 0 to 200 mJ/cm² to a predetermined size portion of a sample thin film having a predetermined thickness formed on a silicon wafer to expose it, treating it with heat, then developing it by immersing in the alkali solution, washing it with water and drying it, subsequently measuring the film thickness using a thin film measurement apparatus, and making a minimum irradiation amount (mJ/cm²) to reduce the film thickness after the exposure by 100% the sensitivity.

The surface roughness of the exposed surface can be measured according to the method described in Waseda University Thesis for Degree No. 2475, “Study on nanostructure measurement by atomic force microscope and its application to device process” written by Masao Nagase, pages 99 to 107, 1996. Specifically, the measurement can be performed for the surface given 30% exposure amount of the electron beam, ultraviolet light or EUV, which exhibited the solubility in the alkali solution using the electron beam, ultraviolet light or EUV light. A sample to be evaluated is made by the same method as in the description for solubility in the alkali solution. The surface roughness of the sample can be measured using the atomic force microscope according to the method of obtaining 10 point average roughness of JIS B0601-1994 that is an indicator of the surface roughness.

An etching rate can be measured by using a dry etching apparatus (TCP 9400 type supplied from LAM Research) to perform the dry etching and calculating the difference of film thickness before and after the dry etching.

In the hyperbranched polymer of the present invention obtained by the method for producing the hyperbranched polymer of the present invention, the core portion has the highly branched structure, therefore, the entanglement among the molecules observed in the linear macromolecules is reduced, and further swelling due to the solvent is also reduced compared with the molecular structure crosslinking the backbone. Furthermore, the acid degradable group contains the repeating unit represented by the formula (I). Thus, in the photolithography, the degradation reaction takes place in the exposed portion by the action of the acid generated from the photo acid generator to produce a hydrophilic group. As a result, it is possible to take a micellar structure having lots of hydrophilic groups in a periphery of the molecule. Thus, the hyperbranched polymer can be efficiently dissolved in the alkali solution, form the fine pattern and is highly sensitive to the EUV light. Moreover, since the acid degradable group contains the repeating unit represented by the formula (I), the hyperbranched polymer has the excellent dry etching resistance. The hyperbranched polymer can be utilized suitably as a base resin of the following resist compositions.

### (Resist Composition)

The resist composition of the present invention includes at least the hyperbranched polymer of the present invention, and can include the photo acid generator, further if necessary an acid diffusion suppressor (acid scavenger), a surfactant and other components, and the solvent.

The amount of the hyperbranched polymer of the present invention to be combined is preferably 4 to 40% by weight and more preferably 4 to 20% by weight relative to the total amount of the resist composition.

The photo acid generator is not particularly limited as long as the acid is generated by irradiating the ultraviolet light, X-ray, or electron beam, can be appropriately selected from those known publicly depending on the purpose, and includes, for example, onium salts, sulfonium salts, halogen-containing triazine compounds, sulfone compounds, sulfonate compounds, aromatic sulfonate compounds and sulfonate compounds of N-hydroxyimide.

The onium salts include, for example, diaryl iodonium salts, triaryl selenonium salts and triaryl sulfonium salts. The diaryl iodonium salts include, for example, diphenyliodonium trifluoromethanesulfonate, bis4-tert-butylphenyliodonium nonafluoromethanesulfonate, bis4-tert-butylphenyliodonium camphor sulfonate, 4-methoxyphenylphenyliodonium hexafluoroantimonate, 4-methoxyphenylphenyliodonium trifluoromethanesulfonate, bis(4-tert-butylphenyl)iodonium tetrafluoroborate, bis(4-tert-butylphenyl)iodonium hexafluorophosphate, bis(4-tert-butylphenyl)iodonium hexafluoroantimonate, and bis(4-tert-butylphenyl)iodonium trifluoromethanesulfonate. The triaryl selenonium salts include, for example, triphenylselenonium hexafluorophosphonium salts, triphenylselenonium fluoroborate salts and triphenylselenonium hexafluoroantimonate salts. The triaryl sulfonium salts include, for example, triphenylsulfonium hexafluorophosphonium salts, triphenylsulfonium hexafluoroantimonate salts, diphenyl-4-thiophenoxyphenylsulfonium hexafluoroantimonate salts, and diphenyl-4-thiophenoxyphenylsulfonium pentafluorohydroxyantimonate salts.

The sulfonium salts include, for example, triphenylsulfonium hexafluorophosphate, triphenylsulfonium hexafluoroantimonate, triphenylsulfonium trifluoromethanesulfonate, triphenylsulfonium nonafluorobutanesulfonate, triphenylsulfonium p-toluenesulfonate, 4-methoxyphenyldiphenylsulfonium hexafluoroantimonate, 4-methoxyphenyldiphenylsulfonium trifluoromethanesulfonate, p-tolyldiphenylsulfonium trifluoromethanesulfonate, 2,4,6-trimethylphenyldiphenylsulfonium trifluoromethanesulfonate, 4-tert-butylphenyldiphenylsulfonium trifluoromethanesulfonate, 4-phenylthiophenyldiphenylsulfonium hexafluorophosphate, 4-phenylthiophenyldiphenylsulfonium hexafluoroantimonate, 1-(2-naphthoylmethyl)thiolanium hexafluoroantimonate, 1-(2-naphthoylmethyl)thiolanium trifluoromethanesulfonate, 4-hydroxy-1-nephthyldimethylsulfonium hexafluoroantimonate, and 4-hydroxy-1-nephthyldimethylsulfonium trifluoromethanesulfonate.

The halogen-containing triazine compounds include, for example, 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolane-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4-dimethoxtstyryl)-4,6-bis(trichloromethyl)-1,3,5-triazine, 2(2,4-dimethoxystyryl)-4,6-bis(trichloromethyl)-1,3,5-triazine, 2(2-methoxystyryl)-4,6-bis(trichloromethyl)-1,3,5-triazine, 2-(4-butoxystyryl)-4,6-bis(trichloromethyl)-1,3,5-triazine and 2-(4-pentyloxystyryl)-4,6-bis(trichloromethyl)-1,3,5-triazine.

The sulfone compounds include, for example, diphenyldisulfone, di-p-tolyldisulfone, bis(phenylsulfonyl)diazomethane, bis(4-chlorophenylsulfonyl)diazomethane, bis(p-tolylsulfonyl)diazomethane, bis(4-tert-butylphenylsulfonyl)diazomethane, bis(2,4-xylylsulfonyl)diazomethane, bis(cyclohexylsulfonyl)diazomethane, (benzoyl)(phenylsulfonyl)diazomethane and phenylsulfonyl acetophenone.

The aromatic sulfonate compounds include, for example, α-benzoylbenzyl p-toluenesulfonate (popular name: benzoin tosylate), β-benzoyl-β-hydroxyphenethyl p-toluenesulfonate (popular name: α-methylolbenzoin tosylate), 1,2,3-benzenetriyltrismethanesylfonate, 2,6-dinitrobenzyl p-toluenesulfonate, 2-nitrobenzyl p-toluenesulfonate, 4-nitrobenzyl p-toluenesulfonate and pyrogallol trimesilate.

The sulfonate compound of N-hydroxyimide include, for example, N-(phenylsulfonyloxy)succinimide, N-(trifluoromethylsulfonyloxy)succinimide, N-(p-chlorophenylsulfonyloxy)succinimide, N-(cyclohexylsulfonyloxy)succinimide, N-(1-naphthylsulfonyloxy)succinimide, N-(benzylsulfonyloxy)succinimide, N-(10-camphar sulfonyloxy)succinimide, N-(trifluoromethylsulfonyloxy)phthalimide, N-(trifluoromethylsulfonyloxy)-5-norbornene-2,3-dicarboxyimide, N-(trifluoromethylsulfonyloxy)naphthalimide, and N-(10-camphar sulfonyloxy)naphthalimide.

As the photo acid generator, the sulfonium salt particularly, triphenylsulfonium trifluoromethanesulfonate; the sulfone compound, particularly, bis(4-tert-butylphenylsulfonyl)diazomethane and bis(cyclohexylsulfonyl)diazomethane are preferable.

The photo acid generator can be used alone or in mixture of two or more. The amount of the photo acid generator to be combined is not particularly limited, and can be appropriately selected depending on the purpose. The amount is preferably 0.1 to 30 parts by weight and more preferably 0.1 to 20 parts by weight relative to 100 parts by weight of the hyperbranched polymer of the present invention.

The acid diffusion inhibitor is not particularly limited as long as it has the actions to control the diffusion of the acid generated from the acid generator by exposure in a resist coat and inhibit unfavorable chemical reactions in an unexposed region, and can be appropriately selected from those known publicly depending on the purpose. For example, nitrogen-containing compounds having one nitrogen atom in the same molecule, compounds having two nitrogen atoms in the same molecule, polyamino compounds and polymers having 3 or more nitrogen atoms, amide group-containing compounds, urea compounds, nitrogen-containing heterocyclic compounds and the like are included.

The nitrogen-containing compounds having one nitrogen atom in the same molecule include, for example, mono(cyclo)alkylamine, di(cyclo)alkylamine, tri(cyclo)alkylamine and aromatic amine. The mono(cyclo)alkylamine includes, for example, 1-cyclohexyl-2-pyrrolidinone, 2-cyclohexyl-2-pyrrolidinone, n-hexylamine, n-heptylamine, n-octylamine, n-nonylamine, n-decylamine and cyclohexylamine. The di(cyclo)alkylamine includes, for example, di-n-butylamine, di-n-pentylamine, di-n-hexylamine, di-n-heptylamine, di-n-octylamine, di-n-nonylamine, di-n-decylamine and cyclohexylmethylamine. The tri(cyclo)alkylamine includes, for example, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, cyclohexyldimethylamine, methyldicyclohexylamine and tricyclohexylamine. The aromatic amine includes, for example, 2-benzylpyridine, aniline, N-methylaniline, N,N-dimethylaniline, 2-methylaniline, 3-methylaniline, 4-methylaniline, 4-nitroaniline, diphenylamine, triphenylamine and naphthylamine.

The nitrogen-containing compound having two nitrogen atoms in the same molecule includes, for example, ethylenediamine, N,N,N′,N′-tetramethylethylenediamine, tetramethylenediamine, hexamethylenediamine, 4,4′-diaminodiphenylmethane, 4,4′-diaminodiphenylether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

The polyamino compounds and polymers having 3 or more nitrogen atoms include, for example, polyethylene imine, polyallylamine, and polymer of N-(2-dimethylaminoethyl)acrylamide.

The amide group-containing compounds include, for example, N-t-butoxycarbonyl-di-n-octylamine, N-t-butoxycarbonyl-di-n-nonylamine, N-t-butoxycarbonyl-di-n-decylamine, N-t-butoxycarbonyldicyclohexylamine, N-t-butoxycarbonyl-1-adamantylamine, N-t-butoxycarbonyl-N-methyl-1-adamantylamine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonyl-hexamethylenediamine, N,N,N′,N′-tetra-t-butoxycarbonyl-hexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N′-di-t-butoxycarbonyl-1,10-diaminodecane, N,N′-di-t-butoxycarbonyl-1,12-diaminododecane, N,N′-di-t-butoxycarbonyl-4,4′-diaminodiphenylmethane, N-t-butoxycarbonyl-benzimidazole, N-t-butoxycarbonyl-2-methylbenzimidazole, N-t-butoxycarbonyl-2-phenylbenzimidazole, formamide, N-methylformamide, N,N-dimethylformamide, acetamide, N-methylacetamide, N,N-dimethylacetamide, propionamide, benzamide, pyrrolidone and N-methylpyrrolidone.

The urea compounds include, for example, urea, methylurea, 1,1-dimethylurea, 1,3-dimethylurea, 1,1,3,3-tetramethylurea, 1,3-diphenylurea and tri-n-butylthiourea.

The nitrogen-containing heterocyclic compounds include, for example, imidazole, 4-methylimidazole, 4-methyl-2-phenylimidazole, benzimidazole, 2-phenylbenzimidazole, pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinic acid amide, quinoline, 4-hydroxyquinoline, 8-oxyquinoline, acridine, piperazine, 1-(2-hydroxyethyl)piperazine, pyrazine, pyrazole, pyridazine, quinozaline, purine, pyrrolidine, piperidine, 3-piperidino-1,2-propanediol, morpholine, 4-methylmorpholine, 1,4-dimethylpiperazine and 1,4-diazabicyclo[2.2.2]octane.

The acid diffusion inhibitor can be used alone or in mixture of two or more. The amount of the acid diffusion inhibitor to be combined is not particularly limited and can be appropriately selected depending on the purpose. The amount is preferably 0.1 to 1000 parts by weight and more preferably 0.5 to 100 parts by weight relative to 100 parts by weight of the photo acid generator.

The surfactant is not particularly limited as long as it has the action to improve a coating property, striation and developing property, and can be appropriately selected from those known publicly depending on the purpose. For example, nonionic surfactants such as polyoxyethylene alkyl ether, polyoxyethylene alkylallyl alcohol, sorbitan fatty acid ester and polyoxyethylene sorbitan fatty acid ester; fluorine based surfactants and silicon based surfactants are included.

The polyoxyethylene alkyl ether includes, for example, polyoxyethylene lauryl ether, polyoxyethylene stearyl ether, polyoxyethylene cetyl ether and polyoxyethylene oleyl ether having 1 to 50 average addition moles of polyoxyethylene. The polyoxyethylene alkylallyl ether includes, for example, polyoxyethylene octylphenol ether and polyoxyethylene nonylphenol ether having 1 to 50 average addition moles of polyoxyethylene. The sorbitan fatty acid ester includes, for example, sorbitan monolaurate, sorbitan monopalmitate, sorbitan monostearate, sorbitan monooleate, sorbitan trioleate and sorbitan tristearate. The nonionic surfactants of the polyoxyethylene sorbitan fatty acid ester include, for example, polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate having 1 to 50 average addition moles of polyoxyethylene. The fluorine based surfactants include, for example, F-top EF301, EF303, EF352 (Shin-Akita Kasei K.K.), Megafac F171, F173, F176, F189, F08 (supplied from Dainippon Ink And Chemicals, Inc.), Fluorad FC430, FC431 (supplied from Sumitomo 3M Ltd.), Asahi Guard AG710, Surflon S-382, SC101, SC102, SC103, SC104, SC105 and SC106 (supplied from Asahi Glass Co., Ltd.). The silicon based surfactants include, for example, organosiloxane polymer KP341 (supplied from Shin-Etsu Chemical Co., Ltd.).

The surfactant can be used alone or in mixture of two or more. The mount of the surfactant to be combined is not particularly limited, and can be appropriately selected depending on the purpose, and is preferably 0.0001 to 5 parts by weight and more preferably 0.0002 to 2 parts by weight relative to 100 parts by weight of the hyperbranched polymer of the present invention.

The other components include, for example, sensitizers, dissolution controlling agents, additives having an acid dissociable group, alkali soluble resins, dyes, pigments, adhesive aids, anti-foaming agents, stabilizers and anti-halation agents.

The sensitizer is not particularly limited as long as it exhibits the actions to absorb the energy of radiation, transmit the energy to the photo acid generator, thereby increasing the amount of the acid generated and has the effect to enhance the apparent sensitivity of the resist composition, and includes, for example, acetophenones, benzophenones, naphthalenes, biacetyl, eosin, rose Bengal, pyrenes, anthracenes and phenothiazines. These sensitizers can be used alone or in mixture of two or more.

The dissolution controlling agent is not particularly limited as long as it appropriately controls dissolution contrast and a dissolution speed when the resist is made, and includes, for example, polyketone and polyspiroketal. These dissolution controlling agents can be used alone or in mixture of two or more.

The additive having the acid dissociable group is not particularly limited as long as it further improves the dry etching resistance, the pattern shape and the adhesiveness to the substrate, and includes, for example, t-butyl 1-adamantanecarboxylate, t-butoxycarbonylmethyl 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantaneacetate, t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, mevalonolactone deoxycholate ester, t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate and mevalonolactone lithocholate ester.

These dissolution controlling agents can be used alone or in mixture of two or more.

The alkali soluble resin is not particularly limited as long as it enhances the alkali solubility of the resist composition of the present invention, and includes, for example, poly(4-hydroxystyrene), partially hydrogenated poly(4-hydroxystyrene), poly(3-hydroxystyrene), poly(3-hydroxystyrene), 4-hydroxystyrene/3-hydroxystyrene copolymers, 4-hydroxystyrene/styrene copolymers, novolak resins, polyvinyl alcohol and polyacrylic acid. Mw is typically 1000 to 1000000 and preferably 2000 to 100000. These alkali soluble resins can be used alone or in mixture of two or more.

The dye or pigment can visualize a latent image of the exposed portion to alleviate the effect of halation upon exposure. The adhesive aids can improve the adhesiveness to the substrate.

The solvent is not particularly limited as long as it can dissolve the components, can be appropriately selected from those capable of being used safely for the resist composition, and includes, for example, ketone, cyclic ketone, propylene glycol monoalkyl ether acetate, alkyl 2-hydroxypropionate, alkyl 3-alkoxypropionate, and other solvents.

The ketone includes, for example, methyl isobutyl ketone, methyl ethyl ketone, 2-butanone, 2-pentanone, 3-methyl-2-butanone, 2-hexanone, 4-methyl-2-pentanone, 3-methyl-2-pentanone, 3,3-dimethyl-2-butanone, 2-heptanone and 2-octanone. The cyclic ketone includes, for example, cyclohexane, cyclopentane, 3-methylcyclopentanone, 2-methylcyclohexanone, 2,6-dimethylcyclohexanone and isophorone. The propylene glycol monoalkyl ether acetate includes, for example, propylene glycol monomethyl ether acetate, propylene glycol monoethyl ether acetate, propylene glycol mono-n-propyl ether acetate, propylene glycol mono-i-propyl ether acetate, propylene glycol mono-n-butyl ether acetate, propylene glycol mono-i-butyl ether acetate, propylene glycol mono-sec-butyl acetate and propylene glycol mono-t-butyl ether acetate. The alkyl 2-hydroxypropionate includes, for example, methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate and t-butyl 2-hydroxypropionate. The alkyl 3-alkoxypropionate includes, for example, methyl 3-methoxypropionate, ethyl 3-methoxypropionate, methyl 3-ethoxypropionate and ethyl 3-ethoxypropionate.

The other solvents can include, for example, n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol, propylene glycol monomethyl ether, propylene glycol monoethyl ether, propylene glycol mono-n-propyl ether, ethyl 2-hydroxy-2-methylpropionate, ethyl ethoxyacetate, ethyl hydroxyacetate, methyl 2-hydroxy-3-methylbutyrate, 3-methoxybutyl acetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetate, ethyl acetoacetate, methyl pyruvate, ethyl pyruvate, N-methylpyrrolidone, N,N-dimethylformamide, N,N-dimethylacetamide, benzylethyl ether, di-n-hexyl ether, diethylene glycol monomethyl ether, diethylene glycol monoethyl ether, γ-butylolactone, toluene, xylene, caproic acid, caprylic acid, octane, decane, 1-octanol, 1-nonanol, benzyl alcohol, benzyl acetate, ethyl benzoate, diethyl oxalate, diethyl maleate, ethylene carbonate and propylene carbonate. These solvents can be used alone or in mixture of two or more.

The resist composition including the hyperbranched polymer of the present invention can further contain the polymer dissolved in the alkali solution by the action of the acid, which is the polymer other than the hyperbranched polymer having the core shell structure containing the repeating unit represented by the formula (I) in the shell portion. The resist composition of the present invention can further contain the polymer that is insoluble in water and soluble in the alkali solution, which is the polymer other than the hyperbranched polymer having the core shell structure containing the repeating unit represented by the formula (I) in the shell portion. These optional polymers include the polymers that dissolve in the alkali solution by the action of the acid, and are insoluble in water and soluble in the alkali solution.

These optional polymers (hereinafter referred to as polymer [A]) that can be used in the present invention can be used without particular limit as long as they satisfy these physical properties, and specifically include, those described in WO2005/061566; as the hyperbranched polymer that dissolves in the alkali solution by the action of the acid, for example, those where core portion:shell portion=2:8 (molar ratio) and acrylic acid occupies 1 to 10 mol % of the shell portion, those where core portion:shell portion=3:7 (molar ratio) and acrylic acid occupies 1 to 35 mol % of the shell portion, those where core portion:shell portion=4:6 (molar ratio) and acrylic acid occupies 1 to 50 mol % of the shell portion, and those where core portion:shell portion=5:5 (molar ratio) and acrylic acid occupies 1 to 60 mol % of the shell portion in the hyperbranched polymers where the core portion is composed of chloromethylstyrene and the shell portion is composed of tert-butyl acrylate ester and acrylic acid. As the polymers that are insoluble in water and soluble in the alkali solution, those where core portion:shell portion=2:8 (molar ratio) and acrylic acid occupies 30 to 99 mol % of the shell portion, those where core portion:shell portion=3:7 (molar ratio) and acrylic acid occupies 45 to 99 mol % of the shell portion, those where core portion:shell portion=4:6 (molar ratio) and acrylic acid occupies 60 to 99 mol % of the shell portion and those where core portion:shell portion=3:7 (molar ratio) and acrylic acid occupies 70 to 99 mol % of the shell portion in the hyperbranched polymers where the core portion is composed of chloromethylstyrene and the shell portion is composed of tert-butyl acrylate ester and acrylic acid are included.

The monomers that can be used include acrylic acid, tert-butyl acrylate, tert-butyl methacrylate, 1-methylcyclohexyl acrylate, 1-methylcyclohexyl methacrylate, adamantyl acrylate, adamantyl methacrylate, 2-(2-methyl)adamantyl acrylate, 2-(2-methyl)adamantyl methacrylate, triethylcarbyl acrylate, 1-ethylnorbornyl acrylate, 1-methylcyclohexyl acrylate, tetrahydropyranyl acrylate, trimethylsilyl acrylate, dimethyl-tert-butylsilyl acrylate, p-vinylphenol, tert-butoxystyrene, α-methyl-4-hydroxystyrene, α-methyl-tert-butoxystyrene, 4-(1-methoxyethoxy)styrene, 4-(1-ethoxyethoxy)styrene, tetrahydropyranyloxystyrene, adamantyloxystyrene, 4-(2-methyl-2-adamantyloxy)styrene, 4-(1-methylcyclohexyloxy)styrene, trimethylsilyloxystyrene, dimethyl-tert-butylsilyloxystyrene, and tetrahydropyranyloxystyrene. Additionally, the structures represented by the following formulae are included.

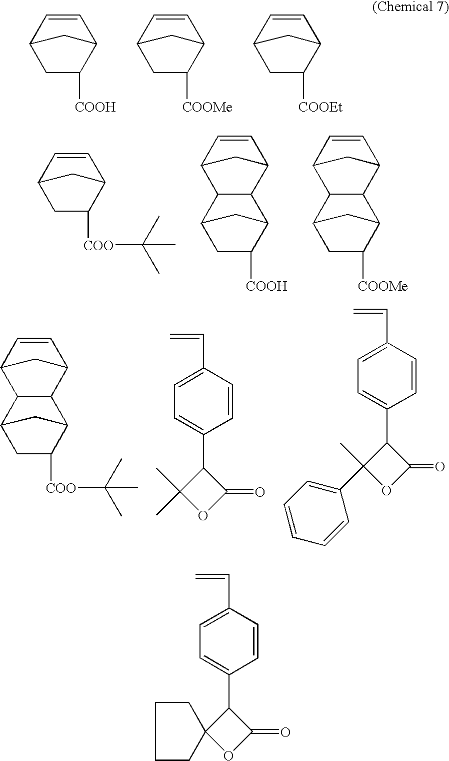

For the amount of the polymer [A] to be combined in the resist composition containing the hyperbranched polymer of the present invention, a sum of the polymers (total amount of the hyperbranched polymer of the present invention and the polymer [A]) is preferably 4 to 40% by weight and more preferably 4 to 20% by weight relative to the entire resist composition.

A mixed ratio of the polymer [A] and the hyperbranched polymer of the present invention is widely variable. When the total amount of the polymer [A] and the hyperbranched polymer of the present invention is 100% by weight, the polymer [A] can be mixed at 1 to 99% by weight, and preferably 5 to 99% by weight.

The resist composition of the present invention can be exposed on the pattern, and subsequently developed to be given a patterning treatment. The resist composition of the present invention can be used suitably in various fields because the fine pattern for producing the VLSI can be formed for the light source of the electron beam, deep ultraviolet light (DUV) and extreme ultraviolet light (EUV) requiring the surface smoothness at a nano order. In the resist composition of the present invention, it is possible to obtain the almost perpendicular edge with no incomplete dissolution on the exposed side by dissolving in the alkali developer with exposure and heating followed by washing.

### EXAMPLES

### Synthesis Example 1

### Synthesis of Hyperbranched Polymer Core Portion A

The following synthesis was performed with reference to the synthesis method described in Krzysztof Matyjaszewski, Macromolecules 29, 1079 (1996) and Jean M. J. Frecht, J. Poly. Sci., 36, 955 (1998).

In a 1,000 mL four-necked reaction vessel equipped with a stirrer and a cooling tube, 49.2 g of 2,2′-bipyridine and 15.6 g of copper chloride(I) were placed under an argon gas atmosphere, 480 mL of chlorobenzene that was a reaction solvent was added, 96.6 g of chloromethylstyrene was dropped over 5 minutes, and the mixture was heated and stirred with keeping an internal temperature constant at 25° C. A reaction time period including a dropping time was 27 minutes.

After termination of the reaction, 300 mL of THF was added to the reaction mixture, and mixed to dissolve a polymer product. By aspirating and filtrating using 400 g of alumina (100 g×4 times) as a filtering element, copper chloride was filtered out, and a filtrate was distilled off under reduced pressure. 700 mL of methanol was added to the resulting filtrate to reprecipitate and yield a highly viscous brown crude product polymer. 500 mL of a mixed solvent of THF:methanol=2:8 was added to 80 g of the crude product polymer, which was then stirred for 3 hours. After the termination of stirring, the polymer was precipitated and the solvent was removed. The resulting purified product was rendered as a hyperbranched polymer core portion A (yield: 72%). A weight average molecular weight (Mw) and a branching degree (Br) were measured. Results are shown in Table 1 below.

TABLE 1

| | | WEIGHT | |
|---|---|---|---|
| | | AVERAGE | |
| | HYPERBRANCHED | MOLECULAR | |
| SYNTHESIS | POLYMER CORE | WEIGHT | BRANCHING |
| EXAMPLE | PORTION | [Mw] | DEGREE |
| 1 | A | 2000 | 0.47 |
| 2 | B | 4000 | 0.48 |
| 3 | C | 8000 | 0.47 |
| 4 | D | 10000 | 0.49 |

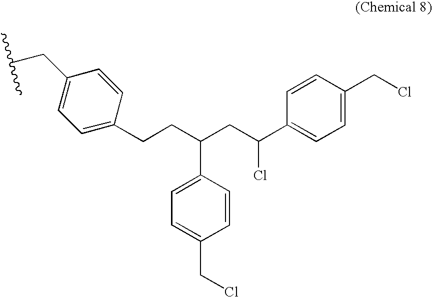

### Synthesis Example 2

### Synthesis of Hyperbranched Polymer Core Portion B

A hyperbranched polymer core portion B was synthesized (yield: 70%) by the same way as in Synthesis Example 1, except that a reaction time in the synthesis of the hyperbranched polymer core portion was 40 minutes. The weight average molecular weight (MW) and the branching degree (Br) were measured. The results of the hyperbranched polymer core portion B are shown in Table 1 above.

### Synthesis Example 3

### Synthesis of Hyperbranched Polymer Core Portion C

A hyperbranched polymer core portion C was synthesized (yield: 70%) by the same way as in Synthesis Example 1, except that a reaction time in the synthesis of the hyperbranched polymer core portion was 60 minutes. The weight average molecular weight (MW) and the branching degree (Br) were measured. The results of the hyperbranched polymer core portion C are shown in Table 1 above.

### Synthesis Example 4

### Synthesis of Hyperbranched Polymer Core Portion D

A hyperbranched polymer core portion D was synthesized (yield: 70%) by the same way as in Synthesis Example 1, except that a reaction time in the synthesis of the hyperbranched polymer core portion was 80 minutes. The weight average molecular weight (MW) and the branching degree (Br) were measured. The results of the hyperbranched polymer core portion D are shown in Table 1 above.

### (Measurement of Weight Average Molecular Weight)

The weight average molecular weight (Mw) of the hyperbranched polymer core portion was obtained by preparing 0.05% by weight of a tetrahydrofuran solution, linking GPC HLC-8020 type apparatus supplied from Tosoh Corporation and two columns TSKgel HXL-M supplied from Tosoh Corporation, and measuring at a temperature of 40° C. Tetrahydrofuran was used as a mobile phase solvent, and styrene was used as a standard substance.

### (Branching Degree)

The branching degree of the hyperbranched polymer was obtained by measuring ¹H-NMR of the product and calculating as follows. That is, the branching degree was calculated by the following mathematical formula using an integral ratio H1° of proton at —CH₂Cl position that appears at 4.6 ppm and an integral ratio H2° of proton at —CHCL position that appears at 4.8 ppm. When the polymerization progresses at both —CH₂Cl position and —CHCl position and the branch is increased, the Br value comes close to 0.5.

$$Br = \frac{\frac{1}{2} H 1 °}{\frac{1}{2} H 1 ° + H 2 °} \qquad ( 2 )$$

### Synthesis Example 5

### Synthesis of methyl 4-vinylbenzoate Ester

This was synthesized with reference to Bulletin Chem. Soc. Japan, 51 (8), 2401-2404. (1978) by the following synthesis method.

In a 1 L reaction vessel equipped with a dropping funnel, 50 g of 4-vinylbenzoic acid and 500 mL of dehydrated benzene were placed at 0° C. under the argon gas atmosphere. Subsequently, 103 g of 1,8-diazabicyclo[5.4.0]-7-undecene (DBU) was injected with a syringe to precipitate a white precipitate. After stirring for 15 minutes, 96 g of methyl iodide was dropped using the dropping funnel. The temperature was kept at 0° C. until one hour after the termination of the dropping, and then raised to room temperature. The mixture was stirred overnight. After the termination of the reaction, to remove DBU, an objective product was extracted in a diethyl ether layer by separatory extraction using 0.5 N hydrochloric acid and 0.5 N sodium hydroxide. The solvent was removed and the temperature was brought back to the room temperature to yield a white solid. It was identified by ¹H NMR that the objective product had been yielded. Yield: 88%.

### Synthesis Example 6

### Synthesis of tert-butyl 4-vinylbenzoate Ester

This was synthesized with reference to Synthesis 833-834 (1982) by the synthesis method shown below.

In a 1 L reaction vessel equipped with a dropping funnel, 91 g of 4-vinylbenzoic acid, 99.5 g of 1,1′-carbodiimidazole, 4-tert-butylpirocathcol and 500 g of dehydrated dimethylformamide were added under the argon gas atmosphere. The temperature was kept at 30° C. and the mixture was stirred for one hour. Subsequently, 93 g of 1,8-diazabicyclo[5.4.0]-7-undecene and 91 g of dehydrated 2-methyl-2-propanol were added thereto, which was then stirred for 4 hours. After the termination of the reaction, 300 mL of diethyl ether and an aqueous solution of 10% potassium carbonate were added to extract an objective product in an ether layer. Subsequently, the diethyl ether layer was dried under reduced pressure to yield a pale yellow liquid. It was identified by ¹H NMR that the objective product had been yielded. Yield: 88%.

### Example 1

### Synthesis of Hyperbranched Polymer

Into the reaction vessel, 0.74 g of copper chloride (I), 2.3 g of 2,2′-bipyridine, 4.6 g of the core portion B obtained in Synthesis Example 2 as a raw material polymer, 206 g of monochlorobenzene and 18.4 g of tert-butyl 4-vinylbenzoate ester obtained in Synthesis Example 6 were added under the argon atmosphere, and the mixture was heated and stirred at 125° C. for 3 hours.

After rapidly cooling the reaction mixture, the catalyst was removed by aspiration filtration using aluminium oxide as the filtering element. The resulting pale yellow filtrate was distilled off under reduced pressure to yield a crude product polymer. The crude product polymer was dissolved in 10 mL of tetrahydrofuran, and 500 mL of methanol was added thereto to reprecipitate. A solid content was separated. The precipitate was washed with methanol to yield a pale yellow solid that was the purified product. Yield: 9.5 g. It was identified by ¹H NMR that a copolymer had been yielded.

De-esterification was performed as follows. 0.6 g of the resulting copolymer was placed in the reaction vessel equipped with a reflux tube, and 30 mL of 1,4-dioxane and 0.6 mL of an aqueous solution of hydrochloric acid were added thereto. The mixture was heated and stirred at 90° C. for 65 minutes.

Subsequently, a reaction crude product was poured in 300 mL of ultra pure water to separate a solid content. Then, 30 mL of 1,4-dioxane was added to dissolve the solid, which was poured again in 300 mL of ultra pure water. The solution was aspirated and filtrated to separate. The resulting solid was dried to make a polymer 1. Yield: 0.48 g. The structure of the polymer 1 is shown below.

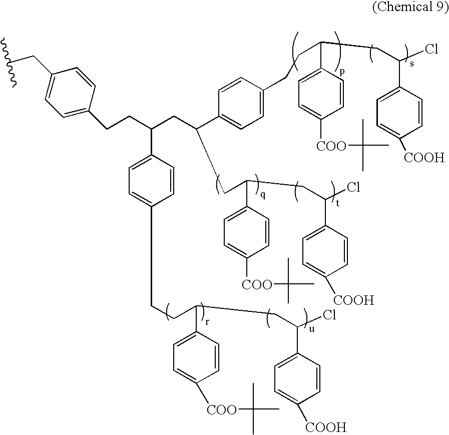

Letters, p, q, r, s, t and u represent integers of 1 or more.

An introduction ratio (constituent ratio) of each constituent unit in the resulting polymer 1 was obtained from ¹H NMR. The weight average molecular weight (M) of the polymer 1 was calculated based on the weight average molecular weight (Mw) of the core portion B obtained in Synthesis Example 2 using the introduction ratio and the molecular weight of each constituent unit. Specifically, it was calculated using the following formula. The results are shown in Table 2 hereinafter.

$$A = \frac{Mw}{b} \\ M = Mw + \frac{A \times C \times c + A \times D \times d}{B} \qquad ( 3 )$$

A: Number of moles of resulting core portion

B: Molar ratio of chloromethylstyrene moiety obtained from NMR

C: Molar ratio of tert-butyl 4-vinylbenzoate ester moiety obtained from NMR

D: Molar ratio of 4-vinylbenzoic acid moiety obtained from NMR

b: Molecular weight of chloromethylstyrene moiety

c: Molecular weight of tert-butyl 4-vinylbenzoate ester moiety

d: Molecular weight of 4-vinylbenzoic acid moiety

Mw: Weight average molecular weight of core portion

M: Weight average molecular weight of hyperbranched polymer

### (Preparation of Resist Composition)

A propylene glycol monomethyl acetate (PEGMEA) solution containing 4.0% by weight of the polymer 1 and 0.16% by weight of triphenylsulfonium trifluoromethanesulfonate as a photo acid generator was made and filtrated with a filter having a fine pore diameter 0.45 μm to prepare a resist composition.

The resulting resist composition was spin-coated on a silicon wafer, and the solvent was evaporate by heating treatment at 90° C. for one minute to make a thin film having a thickness of 100 nm.

(Measurement of Sensitivity Upon Irradiation of Ultraviolet Light) A discharge tube type ultraviolet light irradiation apparatus (DF-245 type Donafix supplied from ATTO Corporation) was used as a light source. A rectangular portion of vertical 10 mm×horizontal 3 mm in the sample thin film having a thickness of about 100 nm formed on the silicon wafer was exposed by irradiating the ultraviolet light having a wavelength of 245 nm with changing an energy amount from 0 mJ/cm² to 50 mJ/cm². The thin film was treated with heat at 100° C. for 4 minutes, and then developed by immersing in an aqueous solution of 2.4% by weight of tetramethylammonium hydroxide (TMAH) at 25° C. for 2 minutes. After washing with water and drying, the film thickness was measured using a thin film measurement apparatus F20 supplied from Filmetrics. The minimum energy amount when the film thickness after the development was zero was made the sensitivity. The results are shown in Table 2 hereinafter.

### (Measurement of Sensitivity Upon Irradiation of Extreme Ultraviolet Light (EUV))

As the light source, synchrotron orbital radiation generated when an orbit of 1 GeV accelerated electron incident from a linear accelerator in the large synchrotron radiation facility, SPring-8 is changed with an electromagnet of a NewSUBARU accumulation ring was used by making monochromatic to the wavelength of 13.5 nm with Mo/Si multilayer film reflection. The sample thin film was prepared in the same way as in the description of the measurement of the sensitivity upon irradiation of the UV light, and the area to which the EUV light was irradiated was the same as in the above. The light was irradiated with the energy at 0.38 to 68 mJ/cm² by changing the exposure time from 1 to 180 seconds. The thin film was treated with heat at 100° C. for 4 minutes, and then developed by immersing in an aqueous solution of 2.4% by weight of tetramethylammonium hydroxide (TMAH) at 25° C. for 2 minutes. After washing with water and drying, the film thickness was measured using the thin film measurement apparatus F20 supplied from Filmetrics. The minimum energy amount when the exposure energy amount was increased and the film thickness after the development was zero was made the sensitivity.

### (Measurement of Surface Roughness)

The surface roughness of the exposed side was obtained with reference to the method described in Waseda University Thesis for Degree No. 2475, “Study on nanostructure measurement by atomic force microscope and its application to device process” written by Masao Nagase, pages 99 to 107, 1996, by using the extreme ultraviolet (EUV) light and measuring the surface of 30% exposure amount at which the solubility in the alkali solution had been exhibited. The rectangular portion of vertical 10 mm×horizontal 3 mm in the sample thin film having the thickness of about 500 nm formed on the silicon wafer was irradiated with EUV light. The thin film was treated with heat at 100° C. for 4 minutes, then developed by immersing in an aqueous solution of 2.4% by weight of tetramethylammonium hydroxide (TMAH) at 25° C. for 2 minutes, and washed with water and dried to make the surface an evaluation sample.

The resulting evaluation sample was measured using an atomic force microscope (SPM-9500J3 supplied from Shimadzu Corporation, according to the method of obtaining 10 point average roughness of JIS B0601-1994 that was the indicator of the surface roughness. The results are shown in Table 2 hereinafter.

### (Measurement of Etching Rate)

The dry etching was given to the sample thin film having the thickness of 200 nm formed on the silicon wafer, and the difference of the film thickness of the resist before and after the dry etching was obtained. The dry etching was performed using a dry etching apparatus TCP9400 type supplied from LAM Research at a micro wave of 13.56 GHz 300 W, at a CF₄ gas flow of 60 cm³/minute and for 60 seconds of etching time. The result was shown as a relative ratio to an etching amount in Comparative Example 1. One showing 0.9 or less was good (A), one showing 0.9 or more and 1.2 or less was acceptable (B), and one showing 1.2 or more was unacceptable (C). The results are shown in Table 2 hereinafter.

### Example 2

### Synthesis of Hyperbranched Polymer

An objective polymer 2 was synthesized in the same way as in Example 1 except polymerizing using 6.8 g of the core portion A, 1.1 g of copper chloride(I), 3.5 g of 2,2′-bipyridine, 274 g of monochlorobenzene and 27.5 g of tert-butyl 4-vinylbenzoate ester.

The constituent ratio and the weight average molecular weight (M) of the resulting polymer 2 were calculated in the same way as in Example 1. The results are shown in Table 2 hereinafter.

### (Preparation of Resist Composition)

A resist composition was prepared in the same way as in Example 1, except using 4.0% by weight of the polymer 2 and 0.16% by weight of triphenylsulfonium nonafluoromethanesulfonate as the photo acid generator, and subsequently the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 3

### Synthesis of Hyperbranched Polymer

In a 500 mL three-necked reaction vessel equipped with the stirrer and the cooling tube, 2.3 g of 2,2′-bipyridine and 0.74 g of copper chloride(I) were placed, 23 mL of the reaction solvent, chlorobenzene was added thereto, 4.6 g of chloromethylstyrene was dropped over 5 minutes, and the mixture was heated and stirred with keeping the internal temperature constant at 125° C. to synthesize the core portion. The reaction time period including the dropping time was 40 minutes. Subsequently, 150 mL of chlorobenzene and 17.1 g of tert-butyl 4-vinylbenzoate ester produced in Synthesis Example 6 were injected with the syringe, and the mixture was heated and stirred at 125° C. for 4 hours to introduce the acid degradable group.

After rapidly cooling the reaction mixture, the catalyst was removed by aspiration filtration using aluminium oxide as the filtrating element. The resulting pale yellow filtrate was distilled off under reduced pressure to yield a crude product polymer. The crude product polymer was dissolved in 10 mL of tetrahydrofuran, and 400 mL of methanol was added to reprecipitate and separate a solid content. The precipitate was washed with methanol to yield a pale yellow solid that was the purified product. Yield: 11.2 g. It was identified by ¹H NMR that a copolymer had been yielded.

### (De-Esterification Step)

0.6 g of the resulting copolymer was placed in the reaction vessel equipped with the reflux tube, and 30 mL of 1,4-dioxane and 0.6 mL of an aqueous solution of hydrochloric acid were added thereto. The mixture was heated and stirred at 90° C. for 65 minutes.

Subsequently, a reaction crude product was poured in 300 mL of ultra pure water to separate a solid content. Then, 30 mL of 1,4-dioxane was added to dissolve the solid, which was then poured again in 300 mL of ultra pure water. The solution was aspirated and filtrated to separate. The resulting solid was dried to make a polymer 3. Yield: 0.44 g.

The introduction ratio (constituent ratio) of each constituent unit in the resulting polymer 3 was obtained from ¹H NMR. The weight average molecular weight (Mw) of the core portion of the polymer 3 was obtained using the weight average molecular weight (Mw) of the core B in Synthesis Example 2 synthesized under the same condition for the combined ratio of monomer, the catalyst and the solvent, the polymerization temperature and time. The weight average molecular weight (M) of the polymer 3 was obtained in the same way as in Example 1. The results are shown in Table 2 hereinafter.

### (Preparation of Resist Composition)

A resist composition was prepared in the same way as in Example 1, except using 4.0% by weight of the polymer 3, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 4

A polymer 4 was synthesized in the same way as in Example 3, except that the reaction time in the core portion polymerization step was 60 minutes, 19.6 g of tert-butyl 4-vinylbenzoate ester was used in the acid degradable group introduction step and the additional amount of monochlorobenzene was 169 mL.

The weight average molecular weight (M) of the polymer 4 was calculated in the same way as in Example 1 based on the weight average molecular weight (Mw) of the core portion obtained by Synthesis Example 3 using the introduction ratio and the molecular weight of each constituent unit. The results are shown in Table 2 hereinafter.

### (Preparation of Resist Composition)

A resist composition was prepared in the same way as in Example 1, except using 4.0% by weight of the polymer 4, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 5

A polymer 5 was synthesized in the same way as in Example 3, except that the reaction time in the core portion polymerization step was 80 minutes, 24.5 g of tert-butyl 4-vinylbenzoate ester was used in the acid degradable group introduction step and the additional amount of monochlorobenzene was 209 g.

The introduction ratio (constituent ratio) of each constituent unit in the resulting polymer 5 was obtained from ¹H NMR. The weight average molecular weight (M) of the polymer 5 was calculated in the same way as in Example 1 based on the weight average molecular weight (Mw) of the core portion obtained by Synthesis Example 4 using the introduction ratio and the molecular weight of each constituent unit. The results are shown in Table 2 hereinafter.

### (Preparation of Resist Composition)

A resist composition was prepared in the same way as in Example 1, except using 4.0% by weight of the polymer 5, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 6

In the reaction vessel in which 396 mg of copper chloride(I), 1.24 g of 2,2′-bipyridine and 2.43 g of the core portion B in Example 1 as the raw material polymer had been placed under the argon gas atmosphere, 31.6 g of monochlorobenzene, 5.25 g of tert-butyl acrylate ester and 1.56 g of methyl 4-vinylbenzoate ester produced in Synthesis Example 6 were injected with the syringe, and the mixture was heated and stirred at 125° C. for 4 hours to introduce the acid degradable group.

After rapidly cooling the reaction mixture, the catalyst was removed by aspiration filtration using aluminium oxide as the filtering element. The resulting pale yellow filtrate was distilled off under reduced pressure to yield a crude product polymer. The crude product polymer was dissolved in 10 mL of tetrahydrofuran, and 400 mL of methanol was added thereto to reprecipitate. A solid content was separated. The precipitate was washed with methanol to yield a pale yellow solid that was the purified product. Yield: 5.5 g. It was identified by ¹H NMR that a copolymer had been yielded. The structure of the polymer 6 is shown below.

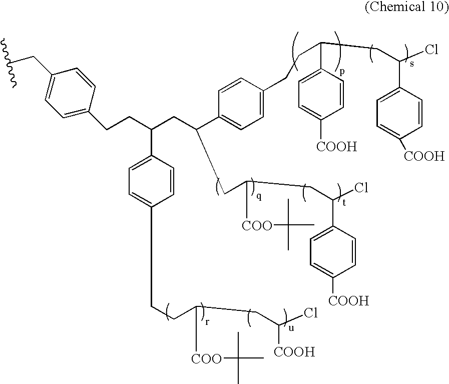

The letters, p, q, r, s, t and u represent the integers of 1 or more.

### (De-Methylesterification Step)

Subsequently, in a 100 mL round bottom flask, 0.5 g of the resulting copolymer, 0.02 g of tetra-n-butyl ammonium bromide, 1.0 g of the aqueous solution of 20% by weight sodium hydroxide and 30 mL of tetrahydrofuran were placed, the reflux tube was attached and the mixture was heated and refluxed for 7 hours. After the termination of the reaction, about 50 mL of 1 N hydrochloric acid was added and stirred to neutralize. Subsequently, the solvent was distilled off. The residue was washed with ultra pure water and dried to yield the polymer 6. Yield: 0.45 g.

The introduction ratio (constituent ratio) of each constituent unit in the resulting polymer 6 was obtained from ¹H NMR. The weight average molecular weight (M) of the polymer 6 was calculated based on the weight average molecular weight of the core portion obtained by Synthesis Example 1 using the introduction ratio and the molecular weight of each constituent unit. Specifically, the calculation was performed using the following formula. The results are shown in Table 2 hereinafter.

$$A = \frac{Mw}{b} \\ M = Mw + \frac{A \times D \times d + A \times E \times e + A \times F \times f}{B} \qquad ( 4 )$$

A: Number of moles of resulting core portion

B: Molar ratio of chloromethylstyrene moiety obtained from NMR

D: Molar ratio of 4-vinylbenzoic acid moiety obtained from NMR

E: Molar ratio of tert-butyl benzoate ester moiety obtained from NMR

F: Molar ratio of acrylic acid moiety obtained from NMR

b: Molecular weight of chloromethylstyrene moiety

d: Molecular weight of 4-vinylbenzoic acid moiety

e: Molecular weight of tert-butyl benzoate ester moiety

f: Molecular weight of acrylic acid moiety

Mw: Weight average molecular weight of core portion

M: Weight average molecular weight of hyperbranched polymer

### (Preparation of Resist Composition)

A resist composition was prepared in the same way as in Example 1, except using 4.0% by weight of the polymer 6, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 7

### Synthesis of Hyperbranched Polymer

An objective polymer 7 was synthesized in the same way as in Example 6, except polymerizing using 2.4 g of the core portion A, 19.4 g of monochlorobenzene, 0.82 g of tert-butyl acrylate ester and 1.56 g of methyl 4-vinylbenzoate ester.

The introduction ratio of each constituent unit and the weight average molecular weight (M) of the resulting polymer 7 were calculated in the same way as in Example 6. The results are shown in Table 2 hereinafter.

### (Preparation of Resist Composition)

A resist composition was prepared in the same way as in Example 1, except using 4.0% by weight of the polymer 7 and using 0.24% by weight of triphenylsulfonium trifluoromethanesulfonate as the photo acid generator, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 8

### Synthesis of Hyperbranched Polymer

An objective polymer 8 was synthesized in the same way as in Example 6 except polymerizing using 2.4 g of the core portion A, 38.1 g of monochlorobenzene, 6.55 g of tert-butyl benzoate ester, and 2.08 g of methyl 4-vinylbenzoate ester.

The constituent ratio and the weight average molecular weight (M) of the resulting polymer 8 were calculated in the same way as in Example 6. The results are shown in Table 2 hereinafter.

### (Preparation of Resist Composition)

A resist composition was prepared in the same way as in Example 1, except using 4.0% by weight of the polymer 8, and subsequently the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 9

### Synthesis of Hyperbranched Polymer

In a 100 mL three-necked reaction vessel equipped with the stirrer and the cooling tube, 1.26 g of 2,2′-bipyridine and 0.40 g of copper chloride(I) were placed, 12 mL of the reaction solvent, chlorobenzene was added thereto, 2.47 g of chloromethylstyrene was dropped over 5 minutes, and the mixture was heated and stirred with keeping the internal temperature constant at 125° C. to synthesize the core portion. The reaction time period including the dropping time was 40 minutes. Subsequently, 20 mL of chlorobenzene, 3.1 g of tert-butyl benzoate ester, and 3.9 g of methyl 4-vinylbenzoate ester were injected with the syringe, and the mixture was heated and stirred at 125° C. for 4 hours to introduce the acid degradable group.

After rapidly cooling the reaction mixture, the catalyst was removed by aspiration filtration using aluminium oxide as the filtrating element. The resulting pale yellow filtrate was distilled off under reduced pressure to yield a crude product polymer. The crude product polymer was dissolved in 10 mL of tetrahydrofuran, and 400 mL of methanol was added to reprecipitate and separate a solid content. The precipitate was washed with methanol to yield a pale yellow solid that was the purified product. Yield: 5.7 g. It was identified by ¹H NMR that a copolymer had been yielded.

### (De-Methylesterification Step)

Subsequently, in a 100 mL round bottom flask, 0.5 g of the resulting copolymer, 0.02 g of tetra-n-butyl ammonium bromide, 1.0 g of the aqueous solution of 20% by weight sodium hydroxide and 30 mL of tetrahydrofuran were placed, the reflux tube was attached and the mixture was heated and refluxed for 5 hours. After the termination of the reaction, about 50 mL of 1 N hydrochloric acid was added and stirred to neutralize. Subsequently, the solvent was distilled off. The residue was washed with ultra pure water and dried to yield a polymer 9. Yield: 0.46 g.

Each constituent unit of the resulting polymer 9 was obtained from ¹H NMR. The weight average molecular weight (M) of the polymer 9 was calculated in the same way as in Example 6 based on the weight average molecular weight (Mw) of the core portion obtained by Synthesis Example 2 using the introduction ratio and the molecular weight of each constituent unit. The results are shown in Table 2 hereinafter.

### (Preparation of Resist Composition)

A resist composition was prepared in the same way as in Example 1, except using 4.0% by weight of the polymer 9, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 10

### Synthesis of Hyperbranched Polymer

An objective polymer 10 was synthesized in the same way as in Example 9, except that the reaction time in the polymerization step of the core portion was 60 minutes, 5.1 g of tert-butyl acrylate ester and 1.4 g of methyl 4-vinylbenzoate ester were polymerized in the step of introducing the acid degradable group, and the reaction time in the de-methylesterification step was 7 hours.

Each constituent unit of the resulting polymer 10 was obtained from ¹H NMR. The weight average molecular weight (M) of the polymer 10 was calculated in the same way as in Example 6, based on the weight average molecular weight of the core portion obtained by Synthesis Example 1 using the introduction ratio and the molecular weight of each constituent unit. The results are shown in Table 2 hereinafter.

### (Preparation of Resist Composition)

A resist composition was prepared in the same way as in Example 1, except using 4.0% by weight of the polymer 10, and subsequently the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### (Preparation of Resist Composition)

A resist composition was prepared in the same way as in Example 1, except that 4.0% by weight of the polymer 2, 8 mol % 2-benzylpyridine as the acid diffusion inhibitor was used, and subsequently the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 12

### Preparation of Resist Composition

A resist composition was prepared in the same way as in Example 1, except that 4.0% by weight of the polymer 2, 8 mol % 2-benzylpyridine as the acid diffusion inhibitor and 0.32% by weight of triphenylsulfonium nonafluoromethanesulfonate as the photo acid generator were used, and subsequently the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 13

### Preparation of Resist Composition

A resist composition was prepared in the same way as in Example 1, except that 4.0% by weight of the polymer 1, 8 mol % 2-benzylpyridine as the acid diffusion inhibitor and 0.32% by weight of triphenylsulfonium trifluoromethanesulfonate as the photo acid generator, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 14

### Synthesis of Hyperbranched Polymer

Under the argon gas atmosphere, 0.40 g of copper chloride(I), 1.25 g of 2,2′-bipyridine, and 2.43 g of the core portion B obtained in Synthesis Example 2 as the raw material polymer, 46.3 g of monochlorobenzene, 18.4 g of tert-butyl 4-vinylbenzoate ester obtained in Synthesis Example 6, and 2.87 g of tert-butyl acrylate ester were placed in the reaction vessel, and heated and stirred at 125° C. for 3 hours.

After rapidly cooling the reaction mixture, the catalyst was removed by aspiration filtration using aluminium oxide as the filtrating element. The resulting pale yellow filtrate was distilled off under reduced pressure to yield a crude product polymer. The crude product polymer was dissolved in 10 mL of tetrahydrofuran, and 300 mL of methanol was added to reprecipitate and separate a solid content. The precipitate was washed with methanol to yield a pale yellow solid that was the purified product. Yield: 6.0 g. It was identified by ¹H NMR that a copolymer had been yielded.

De-esterification was performed as follows. 0.6 g of the resulting copolymer was placed in the reaction vessel equipped with the reflux tube, and 30 mL of 1,4-dioxane and 0.6 mL of an aqueous solution of hydrochloric acid were added thereto. The mixture was heated and stirred at 90° C. for 60 minutes.

Subsequently, a reaction crude product was poured in 300 mL of ultra pure water to separate a solid content. Then, 30 mL of 1,4-dioxane was added to dissolve the solid, which was then poured again in 300 mL of ultra pure water. The solution was aspirated and filtrated to separate. The resulting solid was dried to make a polymer 11. Yield: 0.47 g. The structure of the polymer 11 is shown below.

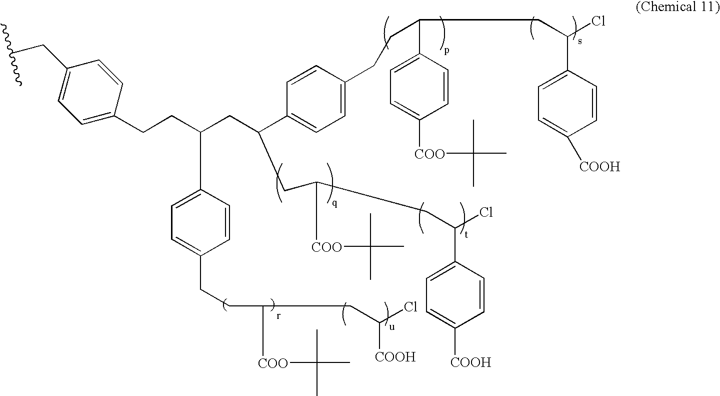

The letters, p, q, r, s, t and u represent integers of 1 or more.

The introduction ratio (constituent ratio) of each constituent unit in the resulting polymer 11 was obtained from ¹H NMR. The weight average molecular weight (M) of the polymer 11 was calculated based on the weight average molecular weight (Mw) of the core portion obtained by Synthesis Example 1 using the introduction ratio and the molecular weight of each constituent unit. Specifically, the calculation was performed using the following formula. The results are shown in Table 2 hereinafter.

$$A = \frac{Mw}{b} \\ M = Mw + \frac{A \times C \times c + A \times D \times d + A \times E \times e + A \times F \times f}{B} \qquad ( 5 )$$

A: Number of moles of resulting core portion

B: Molar ratio of chloromethylstyrene moiety obtained from NMR

C: Molar ratio of tert-butyl 4-vinylbenzoate ester moiety obtained from NMR

D: Molar ratio of 4-vinylbenzoic acid moiety obtained from NMR

E: Molar ratio of tert-butyl benzoate ester moiety obtained from NMR

F: Molar ratio of acrylic acid moiety obtained from NMR

b: Molecular weight of chloromethylstyrene moiety

c: Molecular weight of tert-butyl 4-vinylbenzoate ester moiety

d: Molecular weight of 4-vinylbenzoic acid moiety

e: Molecular weight of tert-butyl benzoate ester moiety

f: Molecular weight of acrylic acid moiety

Mw: Weight average molecular weight of core portion

M: Weight average molecular weight of hyperbranched polymer

### (Preparation of Resist Composition)

A resist composition was prepared in the same way as in Example 1, except that 4.0% by weight of the polymer 11, 8 mol % 2-benzylpyridine as the acid diffusion inhibitor and 0.32% by weight of triphenylsulfonium nonafluoromethanesulfonate as the photo acid generator, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Comparative Example 1

### Synthesis of Hyperbranched Polymer

In the reaction vessel in which 2.7 g of copper chloride(I), 8.3 g of 2,2′-bipyridine and 16.2 g of the core portion B produced in Synthesis Example 2 had been placed under the argon atmosphere, 144 mL of monochlorobenzene and 76 mL of tert-butyl acrylate ester were injected with the syringe, and the mixture was heated and stirred at 120° C. for 5 hours.

After rapidly cooling the reaction mixture, 100 mL of THF was added and stirred, the catalyst was removed by the aspiration filtration using aluminium oxide as the filtrating element. The resulting pale yellow filtrate was distilled off under reduced pressure to yield a crude product polymer. The crude product was dissolved in 50 mL of THF, and then 500 mL of methanol was added to reprecipitate. A reprecipitated solution was centrifuged to separate a solid. This precipitate was washed with methanol to yield the pale yellow solid that was the purified product. Yield: 18.7 g.

### (Deprotection Step)

In the reaction vessel equipped with the reflux tube, 0.6 g of the purified polymer was placed, 30 mL of dioxane and 0.6 mL of hydrochloric acid (30%) were added thereto, and the mixture was heated and stirred at 90° C. for 60 minutes. Subsequently, a reacted crude product was poured in 300 mL of ultra pure water to reprecipitate and yield a solid. The solid was dissolved in 30 mL of dioxane and reprecipitated again. The solid was collected and dried to yield a polymer 12, the polymer of Comparative Example 1. Yield: 0.4 g, percent yield: 66%.

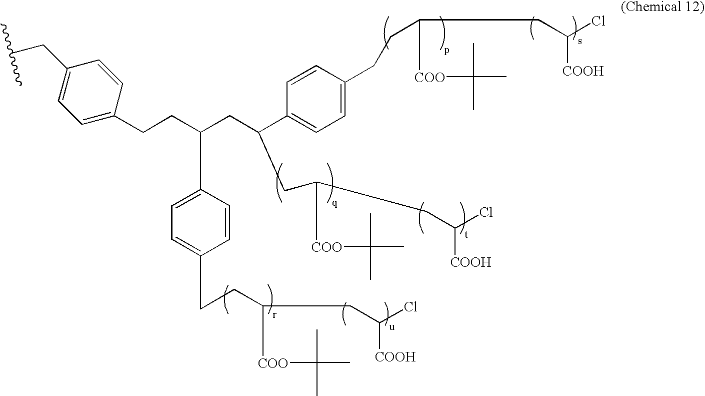

The letters, p, q, r, s, t and u represent the integers of 1 or more.

The introduction ratio (constituent ratio) of each constituent unit in the resulting polymer was obtained from ¹H NMR. The molecular weight of the polymer was calculated based on the weight average molecular weight (Mw) of the core portion obtained by Synthesis Example 2 using the introduction ratio and the molecular weight of each constituent unit. The results are shown in Table 2 hereinafter.

The sensitivity in exposure experiments using the ultraviolet light (254 nm) and the EUV light (13.5 nm), the surface roughness and the etching rate were measured in the same way as in Example 1. The results are shown in Table 2 hereinafter.

### Comparative Example 2

### Synthesis of Hyperbranched Polymer

In the reaction vessel in which 396 mg of copper chloride(I), 1.24 g of 2,2′-bipyridine and 2.43 g of the polymer B had been placed under the argon atmosphere, 68.7 mL of monochlorobenzene and 26.3 mL of tert-butoxystyrene were injected with the syringe, and the mixture was heated and stirred at 125° C. for 2 hours.

After rapidly cooling the reaction mixture, 50 mL of THF was added and stirred, and the catalyst was removed by the aspiration filtration using aluminium oxide as the filtrating element. The resulting pale yellow filtrate was distilled off under reduced pressure to yield a crude product polymer. The crude product was dissolved in 10 mL of THF, and then 400 mL of methanol was added to reprecipitate. A reprecipitated solution was centrifuged to separate a solid. This precipitate was washed with methanol to yield the pale yellow solid that was the purified product. Yield: 6.0 g.

### (Deprotection Step)

In the reaction vessel equipped with the reflux tube, 0.6 g of the purified polymer was placed, 30 mL of dioxane and 0.6 mL of hydrochloric acid (30%) were added thereto, and the mixture was heated and stirred at 90° C. for 60 minutes. Subsequently, a reacted crude product was poured in 300 mL of ultra pure water to reprecipitate and yield a solid. The solid was dissolved in 30 mL of dioxane and reprecipitated again. The solid was collected and dried to yield a polymer of Comparative Example 2. Yield: 0.35 g, percent yield: 58%.

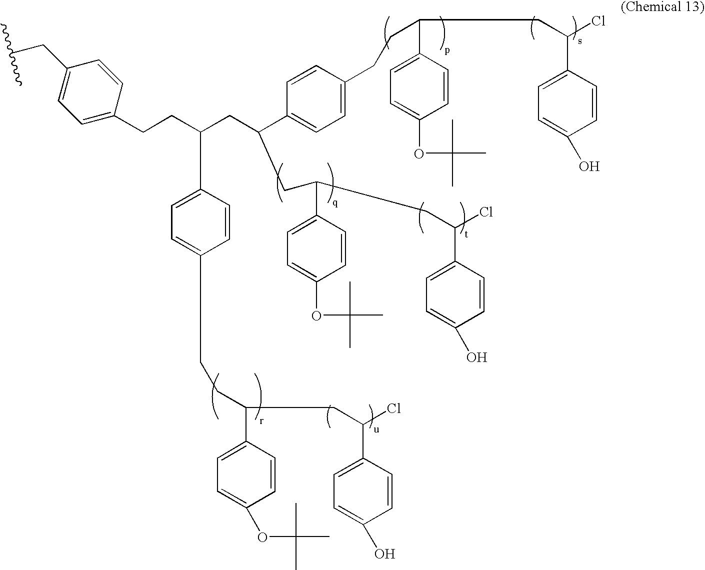

The letters, p, q, r, s, t and u represent the integers of 1 or more.

The sensitivity in exposure experiments using the ultraviolet light (254 nm) and the EUV light (13.5 nm), the surface roughness and the etching rate were measured in the same way as in Example 1. Concerning the surface roughness, the sample thin film having the thickness of about 500 nm formed on the silicon wafer was irradiated with the extreme ultraviolet (EUV) light at 50 mJ/cm², treated with heat at 100° C. for 4 minutes, then developed by immersing in an aqueous solution of 2.4% by weight of tetramethylammonium hydroxide (TMAH) at 25° C. for 2 minutes, and washed with water and dried to make the surface the evaluation sample. The results are shown in Table 2 hereinafter.

### Example 15

### Preparation of Hyperbranched Polymer

The polymer 2 and the polymer 12 were mixed at a ratio by % by weight of 30:70 to make a polymer 13.

### (Preparation of Resist Composition)

A resist composition was prepared in the same way as in Example 1, except that 4.0% by weight of the polymer 13, 8 mol % 2-benzylpyridine as the acid diffusion inhibitor and 0.32% by weight of triphenylsulfonium nonafluoromethanesulfonate as the photo acid generator, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 16

### Preparation of Hyperbranched Polymer

The polymer 2 and the polymer 12 were mixed at a ratio by % by weight of 50:50 to make a polymer 14.

### (Preparation of Resist Composition)

A resist composition was prepared in the same way as in Example 1, except that 4.0% by weight of the polymer 14, 8 mol % 2-benzylpyridine as the acid diffusion inhibitor and 0.32% by weight of triphenylsulfonium nonafluoromethanesulfonate as the photo acid generator, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 hereinafter.

### Example 16

### Preparation of Hyperbranched Polymer

The polymer 2 and the polymer 12 were mixed at a ratio by % by weight of 70:30 to make a polymer 15.

### (Preparation of Resist Composition)

A resist composition was prepared in the same way as in Example 1, except that 4.0% by weight of the polymer 15, 8 mol % 2-benzylpyridine as the acid diffusion inhibitor and 0.32% by weight of triphenylsulfonium nonafluoromethanesulfonate as the photo acid generator, and subsequently, the evaluation sample was made.

### (Evaluation)

The sensitivity in exposure experiments using the ultraviolet light (254 nm) and the EUV light (13.5 nm), the surface roughness and the etching rate were measured in the same way as in Example 1. The results are shown in Table 2 below.

TABLE 2

| | | | | | | | | | | UV | EUV | | |
|---|---|---|---|---|---|---|---|---|---|---|---|---|---|
| | | | | | | | | | | [254 nm] | [13.5 nm] | | |
| | HYPER- | HYPERBRANCHED POLYMER | | | | | | | MOLECU- | SENSI- | SENSI- | ROUGH- | ETCH- |
| | BRANCHED | CONSTITUTION RATIO | | | | | | | LAR | TIVITY | TIVITY | NESS | ING |
| EXAMPLE | POLYMER | CMS | tBuBzA | BzA | tBA | AA | tBS | HS | WEIGHT | [mJ/cm²] | [mJ/cm²] | [nm] | RATE |
| 1 | POLYMER 1 | 32 | 27 | 41 | 0 | 0 | 0 | 0 | 15000 | 1.0 | 2.0 | 0.9 | 0.8[A] |
| 2 | POLYMER 2 | 31 | 31 | 38 | 0 | 0 | 0 | 0 | 7000 | 1.0 | 2.0 | 0.9 | 0.8[A] |
| 3 | POLYMER 3 | 25 | 37 | 38 | 0 | 0 | 0 | 0 | 16000 | 1.0 | 2.0 | 1.1 | 0.8[A] |
| 4 | POLYMER 4 | 35 | 25 | 40 | 0 | 0 | 0 | 0 | 28000 | 1.0 | 2.0 | 1.6 | 0.8[A] |
| 5 | POLYMER 5 | 30 | 35 | 35 | 0 | 0 | 0 | 0 | 35000 | 2.5 | 4.0 | 2.1 | 0.8[A] |
| 6 | POLYMER 6 | 34 | 0 | 16 | 35 | 15 | 0 | 0 | 10000 | 1.5 | 3.0 | 1.2 | 0.9[A] |
| 7 | POLYMER 7 | 50 | 0 | 30 | 12 | 8 | 0 | 0 | 4000 | 1.0 | 2.0 | 0.9 | 0.9[A] |
| 8 | POLYMER 8 | 25 | 0 | 20 | 42 | 13 | 0 | 0 | 32000 | 3.0 | 5.0 | 2.3 | 0.9[A] |
| 9 | POLYMER 9 | 34 | 0 | 30 | 29 | 7 | 0 | 0 | 12000 | 1.5 | 3.0 | 1.1 | 0.9[A] |
| 10 | POLYMER 10 | 35 | 0 | 15 | 40 | 20 | 0 | 0 | 22000 | 2.5 | 4.0 | 1.9 | 0.9[A] |
| 11 | POLYMER 2 | 31 | 31 | 38 | 0 | 0 | 0 | 0 | 7000 | 1.0 | 2.5 | 0.9 | 0.8[A] |
| 12 | POLYMER 2 | 31 | 31 | 38 | 0 | 0 | 0 | 0 | 7000 | 1.0 | 2.0 | 0.9 | 0.8[A] |
| 13 | POLYMER 1 | 32 | 27 | 41 | 0 | 0 | 0 | 0 | 15000 | 1.0 | 2.0 | 0.9 | 0.8[A] |
| 14 | POLYMER 11 | 25 | 31 | 19 | 7 | 18 | 0 | 0 | 7000 | 1.0 | 2.0 | 0.9 | 0.8[A] |
| 15 | POLYMER 13 | — | | | | | | | | 2.0 | 5.0 | 0.9 | 0.8[A] |
| 16 | POLYMER 14 | — | | | | | | | | 1.0 | 3.0 | 0.9 | 0.8[A] |
| 17 | POLYMER 15 | — | | | | | | | | 1.0 | 2.0 | 0.9 | 0.8[A] |
| COMPARATIVE | | 31 | 0 | 0 | 48 | 21 | 0 | 0 | 5000 | 3.0 | 10.0 | 1.1 | 1.0[B] |
| EXAMPLE 1 | | | | | | | | | | | | | |
| COMPARATIVE | | 40 | 0 | 0 | 0 | 0 | 10 | 50 | 15000 | NOT | NOT | 1.5 | 1.3[C] |
| EXAMPLE 2 | | | | | | | | | | EXPOSED | EXPOSED | | |

CMS Chloromethylstyrene moiety
tBuBzA tert-butyl benzoate ester moiety
BzA Benzoic acid moiety
tBA tert-butyl acrylate ester moiety
AA Acrylic acid moiety
tBS tert-butoxystyrene moiety
HS Hydroxystyrene moiety

According to the present invention, it is possible to provide a hyperbranched polymer capable of being utilized as the macromolecular material for nanofabrication focusing on photolithography, and a hyperbranched polymer particularly suitable for EUV lithography and having enhanced surface smoothness, line edge roughness, sensitivity and dry etching resistance. The resist composition containing the hyperbranched polymer of the present invention is excellent in fine pattern formation for producing VLSI.

What is claimed is:

1. A hyperbranched polymer having a core shell structure containing a repeating unit represented by a formula (I) in a shell portion: 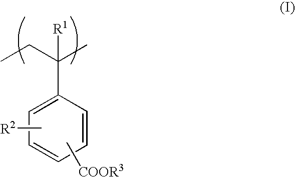
wherein R¹ represents a hydrogen atom or an alkyl group having 1 to 3 carbon atoms; R² represents a hydrogen atom, a straight, branched or cyclic alkyl group having 1 to 30 carbon atoms or an aryl group having 6 to 30 carbon atoms; R³ represents a hydrogen atom, a straight, branched or cyclic alkyl group having 1 to 40 carbon atoms, a trialkylsilyl group (the alkyl groups are independent of one another and respectively have 1 to 6 carbon atoms), an oxoalkyl group (the alkyl group has 4 to 20 carbon atoms), or a group represented by a formula (I): 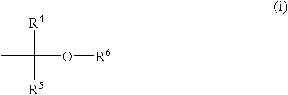
wherein R⁴ represents a straight, branched or cyclic alkyl group having 1 to 10 carbon atoms; and R⁵ and R⁶ are independent of one another and represent a straight, branched or cyclic alkyl group having 1 to 10 carbon atoms, or R⁵ and R⁶ forms a ring together.

2. The hyperbranched polymer according to claim 1 wherein R¹ is the hydrogen atom in the formula (I).

3. The hyperbranched polymer according to claim 1 wherein R² is the hydrogen atom in the formula (I).

4. The hyperbranched polymer according to claim 1 wherein the repeating unit represented by the formula (I) is selected from the group consisting of vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1-n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butylolactone, β-(4-vinylbenzoyl)oxy-γ-butylolactone, γ-(4-vinylbenzoyl)oxy-γ-butylolactone, α-methyl-α-(4-vinylbenzoyl)oxy-γ-butylolactone, β-methyl-β-(4-vinylbenzoyl)oxy-γ-butylolactone, γ-methyl-γ-(4-vinylbenzoyl)oxy-γ-butylolactone, α-ethyl-α-(4-vinylbenzoyl)oxy-γ-butylolactone, β-ethyl-β-(4-vinylbenzoyl)oxy-γ-butylolactone, γ-ethyl-γ-(4-vinylbenzoyl)oxy-γ-butylolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone.

5. The hyperbranched polymer according to claim 1 wherein the hyperbranched polymer has a core portion obtained by polymerizing at least a monomer represented by a formula (II): 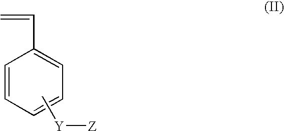
wherein Y represents an alkylene group having 1 to 10 carbon atoms that may contain a hydroxyl group or a carboxyl group, and Z represents a halogen atom.

6. The hyperbranched polymer according to claim 5 wherein the monomer represented by the formula (II) is chloromethylstyrene.

7. The hyperbranched polymer according to claim 1 wherein a weight average molecular weight of the hyperbranched polymer is 500 to 150,000.

8. The hyperbranched polymer according to claim 1 wherein the monomer that composes the core portion of the hyperbranched polymer is contained at 10 to 90 mol % relative to entire monomers that compose the hyperbranched polymer.

9. The hyperbranched polymer according to claim 1 wherein the monomer that gives the repeating unit represented by the formula (I) is contained at 10 to 90 mol % relative to entire monomers that compose the hyperbranched polymer.

10. The hyperbranched polymer according to claim 1 wherein the monomer that gives the repeating unit represented by the formula (I) wherein R³ is the hydrogen atom is contained at 0 to 80 mol % relative to entire monomer units that compose the hyperbranched polymer.

11. The hyperbranched polymer according to claim 1 wherein an amount of a metal element contained in the hyperbranched polymer is less than 100 ppb.

12. A resist composition containing a hyperbranched polymer having a core shell structure containing a repeating unit represented by a formula (I) in a shell portion: 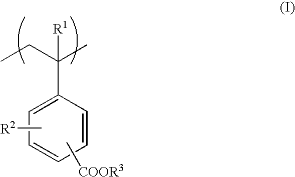
wherein R¹ represents a hydrogen atom or an alkyl group having 1 to 3 carbon atoms; R² represents a hydrogen atom, a straight, branched or cyclic alkyl group having 1 to 30 carbon atoms or an aryl group having 6 to 30 carbon atoms; R³ represents a hydrogen atom, a straight, branched or cyclic alkyl group having 1 to 40 carbon atoms, a trialkylsilyl group (the alkyl groups are independent of one another and respectively have 1 to 6 carbon atoms), an oxoalkyl group (the alkyl group has 4 to 20 carbon atoms), or a group represented by a formula (I): 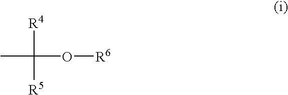
wherein R⁴ represents a straight, branched or cyclic alkyl group having 1 to 10 carbon atoms; and R⁵ and R⁶ are independent of one another and represent a straight, branched or cyclic alkyl group having 1 to 10 carbon atoms, or R⁵ and R⁶ forms a ring together.

13. The resist composition according to claim 12 further containing a photo acid generator.

14. The resist composition according to claim 13 further containing an acid diffusion inhibitor.

15. The resist composition according to claim 12 further containing a polymer that dissolves in an alkali solution by an action of an acid, which is the polymer other than the hyperbranched polymer having a core shell structure containing a repeating unit represented by the formula (I) in a shell portion.

16. The resist composition according to claim 12 further containing a polymer that is insoluble in water and soluble in the alkali solution, which is the polymer other than the hyperbranched polymer having the core shell structure containing the repeating unit represented by the formula (I) in the shell portion.
